(19) United States
(12) Patent Application Publication
(10) Pub. No.: US 2025/0089463 A1
(43) Pub. Date: Mar. 13, 2025

(54) DISPLAY DEVICE AND METHOD OF FABRICATING THE SAME

(71) Applicant: Samsung Display Co., LTD., Yongin-si (KR)

(72) Inventors: Hyun Eok SHIN, Yongin-si (KR); Joon Yong PARK, Yongin-si (KR); Su Kyoung YANG, Yongin-si (KR); Dong Min LEE, Yongin-si (KR)

(21) Appl. No.: 18/633,458

(22) Filed: Apr. 11, 2024

(30) Foreign Application Priority Data
Sep. 12, 2023 (KR) 10-2023-0121253

(51) Int. Cl. H10K 59/122; H10K 59/12

(52) U.S. Cl. CPC H10K 59/122; H10K 59/1201

(57) ABSTRACT

A display device includes a substrate including a first emission area, a transmissive area, and a non-emission area disposed between the first emission area and the transmissive area; a pixel-defining layer disposed on the non-emission area of the substrate and defining a first opening; a bank structure disposed on the pixel-defining layer, defining a second opening, and including different materials; and a first light-emitting element disposed on the first emission area of the substrate and in contact with the bank structure, where the bank structure includes a first bank layer including a conductive material; and a second bank layer disposed on the first bank layer and including tips that protrude on opposite sides of the second bank layer toward the first opening and the transmissive area than side surfaces of the first bank layer.

This application claims priority to Korean Patent Application No. 10-2023-0121253, filed on Sep. 12, 2023, and all the benefits accruing therefrom under 35 U.S.C. § 119, the content of which in its entirety is herein incorporated by reference.

### BACKGROUND

### 1. Field

The disclosure relates to a display device and a method of fabricating the same.

### 2. Description of the Related Art

As the information-oriented society evolves, various demands for display devices are ever increasing. In an embodiment, display devices are being employed by a variety of electronic devices such as smart phones, digital cameras, laptop computers, navigation devices, and smart televisions. Display devices may be flat-panel display devices such as a liquid-crystal display device, a field emission display device, and an organic light-emitting display device. Among such flat panel display devices, a light-emitting display device includes a light-emitting element that may emit light on its own, so that each of the pixels of the display panel may emit light by themselves. Accordingly, a light-emitting display device may display images without a backlight unit that supplies light to the display panel.

Recently, as various electronic devices have developed, the demand for high-resolution display devices is increasing. Since high-resolution display devices desire relatively high pixel density, the spacing between light-emitting elements in each emission area may be narrowed. Therefore, a high-resolution display device may be formed via a patterning process that forms individual pixels rather than a mask process.

### SUMMARY

Features of the disclosure provide a high-resolution display device with a transmissive area.

It should be noted that features of the disclosure are not limited to the above-mentioned feature; and other features of the disclosure will be apparent to those skilled in the art from the following descriptions.

In an embodiment of the disclosure, a display device includes a substrate including a first emission area, a transmissive area, and a non-emission area disposed between the first emission area and the transmissive area; a pixel-defining layer disposed on the non-emission area of the substrate and defining a first opening; a bank structure disposed on the pixel-defining layer, defining a second opening, and including different materials; and a first light-emitting element disposed on the first emission area of the substrate and in contact with the bank structure, where the bank structure includes a first bank layer including a conductive material; and a second bank layer disposed on the first bank layer and including tips that protrude on opposite sides of the second bank layer further toward the first opening and the transmissive area than side surfaces of the first bank layer.

In an embodiment, a display device may further include a tip of the tips of the second bank layer that protrudes toward the transmissive area; and the tip of the second bank layer that protrudes toward the first opening form undercuts with the side surfaces of the first bank layer.

In an embodiment, the first light-emitting element may include an anode electrode disposed on the substrate; an emissive layer on the anode electrode in line with the first opening; and a cathode electrode on the emissive layer, and where the emissive layer and the cathode electrode contact a side surface of the side surfaces of the first bank layer in the second opening.

In an embodiment, the cathode electrode may cover an entirety of the emissive layer on the side surfaces of the first bank layer.

In an embodiment, the first bank layer may include aluminum, and the second bank layer includes titanium.

In an embodiment, a display device may further include an organic pattern disposed on the second bank layer, surrounding the first opening, and including a same material as that of the emissive layer; and an electrode pattern disposed on the organic pattern and including a same material as that of the cathode electrode.

In an embodiment, the emissive layer and the organic pattern may be spaced apart from each other, and where the cathode electrode and the electrode pattern are spaced apart from each other.

In an embodiment, the organic pattern and the electrode pattern may not overlap with a tip of the tips of the second bank layer that protrudes toward the transmissive area.

In an embodiment, the second opening may surround an entirety of the first opening in a plan view.

In an embodiment, the non-emission area may surround an entirety of the first emission area in the plan view, and where the transmissive area surrounds the non-emission area.

In an embodiment, the transmissive area may include an optical device.

In an embodiment, the display device may further include a second emission area spaced apart from the first emission area with the non-emission area and the transmissive area therebetween; and a second light-emitting element disposed on the substrate in line with the second emission area.

In an embodiment, a display device may further include a metal line overlapping with the transmissive area and electrically connecting the first light-emitting element with the second light-emitting element.

In an embodiment, the metal line may include the first bank layer and the second bank layer in the transmissive area.

In an embodiment, the first bank layer and the second bank layer included in the bank structure in the non-emission area may be integral with the first bank layer and the second bank layer included in the metal line in the transmissive area.

In an embodiment, the first emission area and the second emission area may be connected with each other by the metal line in a plan view.

In an embodiment, the transmissive area may be surrounded by the tip of the second bank layer that protrudes toward the transmissive area in the plan view.

In an embodiment of the disclosure, a method of fabricating a display device, the method includes forming a sacrificial layer on each of a plurality of anode electrodes spaced apart from one another on an emission area of a substrate, the substrate including the emission area and a transmissive area, forming a pixel-defining layer disposed on the sacrificial layer and the substrate and covering an entirety of the sacrificial layer and the substrate, and forming a first bank material layer and a second bank material layer on the pixel-defining layer; defining a first hole overlapping with the plurality of anode electrodes, penetrating the first bank material layer and the second bank material layer and exposing the pixel-defining layer overlapping the plurality of anode electrodes, and defining a second hole overlapping with the transmissive area, penetrating the first bank material layer and the second bank material layer and exposing the pixel-defining layer in the transmissive area; performing wet etching on sidewalls of the first hole and the second hole to form a tip where the second bank material layer protrudes than sidewalls of the first bank material layer; removing portions of the pixel-defining layer overlapping with the plurality of anode electrodes and the transmissive area by dry etching, removing portions of the sacrificial layer overlapping with the plurality of anode electrodes by wet etching, to exposes the plurality of anode electrodes; forming an emissive layer and a cathode electrode on the plurality of anode electrodes, the substrate overlapping with the transmissive area and the second bank material layer, and forming a first encapsulation layer over the cathode electrode; and removing the emissive layer, the cathode electrode and the first encapsulation layer except the emissive layer, the cathode electrode and the first encapsulation layer disposed in and around the emission area, where the second bank material layer may include the tip that protrudes toward the transmissive area.

In an embodiment, the tip of the second bank material layer that protrudes toward the transmissive area may not overlap with the emissive layer or the cathode electrode.

In an embodiment, the transmissive area may be surrounded by the tip that protrudes toward the transmissive area in a plan view.

In an embodiment of the disclosure, a display device may include a bank structure including tips protruding toward an emission area and a transmissive area. Accordingly, it is possible to form a high-resolution display device without a mask and to form a transmissive area without any additional process. Therefore, the display device in the embodiment may be used in a variety of ways electronic devices in which a transmissive area and high-resolution are desired.

It should be noted that effects of the disclosure are not limited to those described above and other effects of the disclosure will be apparent to those skilled in the art from the following descriptions.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view showing an embodiment of an electronic device according to the disclosure.

FIG. 2 is a perspective view showing an embodiment of a display device included in an electron device according to the disclosure.

FIG. 3 is a schematic cross-sectional view of the display device of FIG. 2.

FIG. 4 is a schematic plan view of the display layer of FIG. 3.

FIG. 5 is a plan view showing a layout of emission areas in the first display area of FIG. 2.

FIG. 6 is a schematic cross-sectional view of the first display area, taken along line X1-X1′ of FIG. 5.

FIG. 7 is an enlarged cross-sectional view of a first emission area of FIG. 6.

FIG. 8 is an enlarged cross-sectional view of area A of FIG. 6.

FIG. 9 is a plan view showing a layout of emission areas in the second display area of FIG. 2.

FIG. 10 is a cross-sectional view taken along line X3-X3′ of FIG. 9.

FIG. 11 is a cross-sectional view taken along line X5-X5′ of FIG. 9.

FIG. 12 is a cross-sectional view taken along line X7-X7′ of FIG. 9.

FIGS. 13 to 22 are cross-sectional views showing processes of fabricating the display device in the second display area.

### DETAILED DESCRIPTION

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Hereinafter, embodiments of the disclosure will be described in detail with reference to the accompanying drawings.

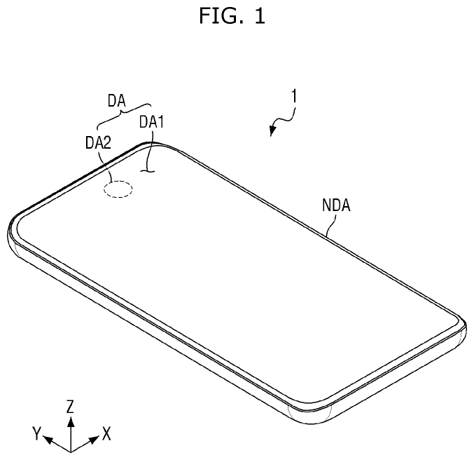

FIG. 1 is a perspective view showing an embodiment of an electronic device 1.

Referring to FIG. 1, an electronic device 1 displays a moving image or a still image. The electronic device 1 may refer to any electronic device that provides a display screen. In an embodiment, the electronic device 1 may include a television set, a laptop computer, a monitor, an electronic billboard, the Internet of Things devices, a mobile phone, a smart phone, a tablet personal computer (“PC”), an electronic watch, a smart watch, a watch phone, a head-mounted display device, a mobile communications terminal, an electronic notebook, an electronic book, a portable multimedia player (“PMP”), a navigation device, a game console and a digital camera, a camcorder, etc., for example.

In FIG. 1, a first direction (x-axis direction), a second direction (y-axis direction) and a third direction (z-axis direction) are defined. The first direction (x-axis direction) and the second direction (y-axis direction) may be perpendicular to each other, the first direction (x-axis direction) and the third direction (z-axis direction) may be perpendicular to each other, and the second direction (y-axis direction) and the third direction (z-axis direction) may be perpendicular to each other. As used herein, a direction may refer to the direction indicated by the arrow as well as the opposite direction, unless specifically stated otherwise. If it is necessary to discern between such two opposite directions, one of the two directions may be referred to as “one side in the direction,” while the other direction may be referred to as “the opposite side in the direction.” In FIG. 1, the side indicated by an arrow indicative of a direction is referred to as one side in the direction, while the opposite side is referred to as the opposite side in the direction.

In the following description of the surfaces of the electronic device 1 or the elements of the electronic device 1, the surface facing one side where images are displayed, i.e., the side indicated by the arrow in the third direction (z-axis direction) will be also referred to as the upper surface, while the opposite surface will be also referred to as the lower surface, for convenience of illustration. It should be understood, however, that the disclosure is not limited thereto. The surfaces and the opposite surface of each of the elements may be also referred to as a front surface and a rear surface, respectively, or may be also referred to as a first surface and a second surface, respectively. In addition, in the description of relative positions of the elements of the electronic device 1, one side in the third direction (z-axis direction) may be also referred to as the upper side while the opposite side in the third direction (z-axis direction) may be also referred to as the lower side.

The shape of the electronic device 1 may be modified in a variety of ways. In an embodiment, the electronic device 1 may have shapes such as a rectangle with longer lateral sides, a rectangle with longer vertical sides, a square, a quadrangle with rounded corners (vertices), other polygons, a circle, etc., for example.

The electronic device 1 may include the display area DA and a non-display area NDA. In the display area DA, images may be displayed. In the non-display area NDA, images are not displayed. The display area DA may be also referred to as an active area, while the non-display area NDA may also be also referred to as an inactive area.

The display area DA may include a first display area DA1 and a second display area DA2. The first display area DA1 may occupy most of the electronic device 1. The second display area DA2 may be generally disposed in the center of one edge of the electronic device 1. An optical device for adding a variety of features to the electronic device 1 may be placed in the second display area DA2. Although one second display area DA2 is shown in the drawings, the disclosure is not limited thereto. More than one second display areas DA2 may be formed.

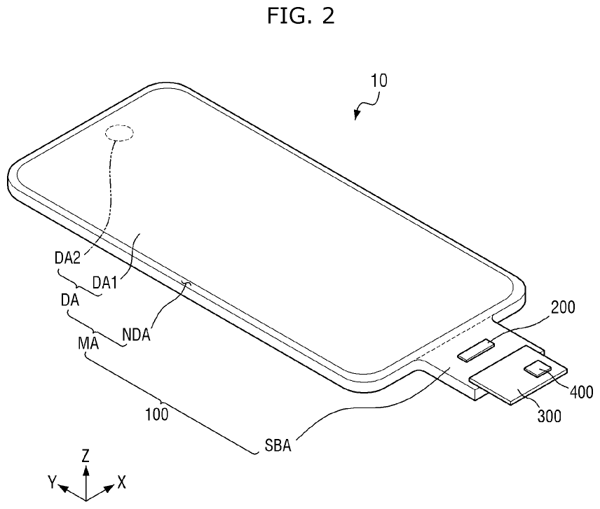

FIG. 2 is a perspective view showing an embodiment of a display device 10 included in the electronic device 1.

Referring to FIG. 2, the electronic device 1 in the embodiment may include the display device 10. The display device 10 may provide a display screen where images are displayed in the electronic device 1. In embodiments, the display device 10 may include an inorganic light-emitting diode display device, an organic light-emitting display device, a quantum-dot light-emitting display device, a plasma display device, a field emission display device, etc. In the following description, an organic light-emitting diode display device is employed in an embodiment of the display device, but the disclosure is not limited thereto. Any other display device may be employed as long as the technical idea of the disclosure may be equally applied.

The display device 10 may have a shape similar to that of the electronic device 1 in a plan view. In an embodiment, the display device 10 may have a shape similar to a rectangle having shorter sides in the first direction (x-axis direction) and longer sides in the second direction (y-axis direction), for example. The corners where the shorter sides in the first direction (x-axis direction) meet the longer sides in the second direction (y-axis direction) may be rounded with a predetermined curvature. It should be understood, however, that the disclosure is not limited thereto. The corners may be formed at a right angle. The shape of the display device 10 in a plan view is not limited to a quadrangular shape, but may be formed in a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA. The main area MA may include the display area DA including pixels for displaying images, and the non-display area NDA disposed around the display area DA. The display area DA may include a first display area DA1 and a second display area DA2.

The first display area DA1 may emit light from a plurality of emission areas or a plurality of open areas. In an embodiment, the first display area DA1 may include pixel circuits including switching elements, an inorganic pixel-defining film that defines the emission areas or the open areas, and self-light-emitting elements, for example.

In an embodiment, the self-light-emitting element may include, but is not limited to, at least one of: an organic light-emitting diode including an organic emissive layer, a quantum-dot light-emitting diode (“quantum LED”) including a quantum-dot emissive layer, an inorganic light-emitting diode (“inorganic LED”) including an inorganic semiconductor, and a micro light-emitting diode (“micro LED”), for example.

The second display area DA2 may emit light from a plurality of emission areas or a plurality of open areas, and may also include a transmissive area. Accordingly, in the second display area DA2 that may transmit light, an optical device may be disposed thereunder. This will be described later again.

The non-display area NDA may be disposed on the outer side of the display area DA. The non-display area NDA may be defined as the edge area of the main area MA of the display panel 100. The non-display area NDA may include a gate driver and a plurality of lines, which will be described later.

The subsidiary area SBA may be extended from one side of the main area MA. The subsidiary area SBA may include a flexible material that may be bent, folded, or rolled. In an embodiment, when the subsidiary area SBA is bent, the subsidiary area SBA may overlap the main area MA in the third direction (z-axis direction), for example. The subsidiary area SBA may include display pads connected to the display driver 200 and the circuit board 300. In another embodiment, the subsidiary area SBA may be eliminated, and the display driver 200 and the display pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (“IC”) and may be attached on the display panel 100 by a chip-on-glass (“COG”) technique, a chip-on-plastic (“COP”) technique, or ultrasonic bonding. In an embodiment, the display driver 200 may be disposed in the subsidiary area SBA and may overlap with the main area MA in the thickness direction as the subsidiary area SBA is bent, for example. In another embodiment, the display driver 200 may be disposed (e.g., mounted) on the circuit board 300.

The circuit board 300 may be attached on the display pads of the display panel 100 using an anisotropic conductive film (“ACF”). Lead lines of the circuit board 300 may be electrically connected to the display pads of the display panel 300. The circuit board 300 may be a flexible printed circuit board (“FPCB”), a printed circuit board (“PCB”), or a flexible film such as a chip-on-film (“COF”).

The touch driver 400 may be disposed (e.g., mounted) on the circuit board 300. The touch driver 400 may be connected to a touch sensor unit of the display panel 100. The touch driver 400 may supply a touch driving signal to a plurality of touch electrodes of the touch sensor unit and may sense a change in the capacitance between the plurality of touch electrodes. In an embodiment, the touch driving signal may be a pulse signal having a predetermined frequency, for example. The touch driver 400 may determine whether there is an input and may find the coordinates of the input based on the amount of the change in the capacitance between the touch electrodes. The touch driver 400 may be implemented as an IC.

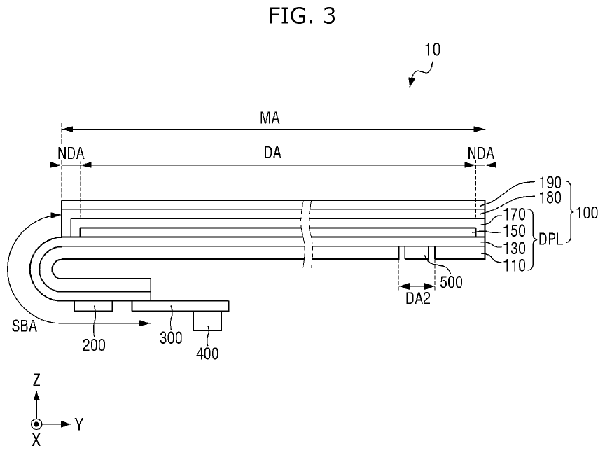

FIG. 3 is a schematic cross-sectional view of the display device 10 of FIG. 2.

Referring to FIG. 3, the display panel 100 may include a display layer DPL, a touch sensor layer 180, and a color filter layer 190. In addition, the display layer DPL may include a substrate 110, a thin-film transistor layer 130, a display element layer 150, and a thin-film encapsulation layer 170.

The substrate 110 may be a base substrate or a base member. The substrate 110 may be a flexible substrate that may be bent, folded, or rolled. In an embodiment, the substrate 110 may include, but is not limited to, a polymer resin such as polyimide (“PI”), for example. In another embodiment, the substrate 110 may include a glass material or a metal material.

The thin-film transistor layer 130 may be disposed on the substrate 110. The thin-film transistor layer 130 may be disposed in the display area DA, the non-display area NDA and the subsidiary area SBA. The thin-film transistor layer 130 may include a plurality of thin-film transistors and a plurality of lines forming pixel circuits. Each of the plurality of thin-film transistors may include an active layer, a source electrode, a drain electrode, and a gate electrode.

The thin-film transistors, the gate lines, the data lines and the voltage lines included in the thin-film transistor layer 130 may be disposed in the display area DA. The gate control lines and a plurality of fan-out lines included in the thin-film transistor layer 130 may be disposed in the non-display area NDA and the subsidiary area SBA.

The display element layer 150 may be disposed on the thin-film transistor layer 130. The display element layer 150 may be disposed in the display area DA. The display element layer 150 may include a plurality of light-emitting elements each including an anode electrode, a cathode electrode and an emissive layer to emit light, and an inorganic pixel-defining layer that defines pixels. In an embodiment, the emissive layer may be an organic emissive layer including or consisting of an organic material, for example.

When the anode electrode receives a voltage and the cathode electrode receives a cathode voltage through the thin-film transistors of the thin-film transistor layer 130 in the light-emitting element in the embodiment of the disclosure, the holes and electrons may move to the organic light-emitting layer through the hole transporting layer and the electron transporting layer, respectively, such that they combine in the organic light-emitting layer to emit light. In another embodiment, the light-emitting elements may include quantum-dot light-emitting diodes each including a quantum-dot emissive layer, inorganic light-emitting diodes each including an inorganic semiconductor, or micro light-emitting diodes.

The thin-film encapsulation layer 170 may be disposed on the display element layer 150. The thin-film encapsulation layer 170 may overlap the display area DA and the non-display area NDA. The thin-film encapsulation layer 170 may cover the upper and side surfaces of the display element layer 150, and may protect the display element layer 150. The thin-film encapsulation layer 170 may include at least one inorganic film and at least one organic film for encapsulating the display element layer 150.

The touch sensor layer 180 may be disposed on the thin-film encapsulation layer 170. The touch sensor layer 180 may overlap the display area DA and the non-display area NDA. The touch sensor layer 180 may include a plurality of touch electrodes for sensing a user's touch by capacitive sensing, and touch lines connecting the plurality of touch electrodes with the touch driver 400. In an embodiment, the touch sensor layer 180 may sense a user's touch by mutual capacitance sensing or self-capacitance sensing, for example.

According to the embodiment, the display device 10 may include an optical device 500. The optical device 500 may be disposed under the substrate 110 in the second display area DA2. The optical device 500 may output or receive light in infrared, ultraviolet, and visible ranges. In an embodiment, the optical device 500 may include a proximity sensor, an illumination sensor, a camera, etc., for example. The optical device 500 may be disposed in line with a transmissive area TA, which will be described later. This will be described in detail later.

The color filter layer 190 may be disposed on the touch sensor layer 180. The color filter layer 190 may overlap the display area DA and the non-display area NDA. The color filter layer 190 may include a plurality of color filters associated with the plurality of emission areas, respectively. Each of the color filters may selectively transmit light of a particular wavelength and block or absorb lights of other wavelengths. The color filter layer 190 may absorb some of lights introduced from the outside of the display device 10 to reduce the reflection of external light. Accordingly, the color filter layer 190 may prevent distortion of colors due to the reflection of external light.

Since the color filter layer 190 is disposed directly on the touch sensor layer 180, the display device 10 may desire no separate substrate for the color filter layer 190. Therefore, the thickness of the display device 10 may be relatively small.

As shown in FIG. 3, a portion of the display layer DPL overlapping with the subsidiary area SBA may be bent. When a portion of the display layer DPL is bent, the display driver 200, the circuit board 300 and the touch driver 400 may overlap with the main area MA in the third direction (z-axis direction).

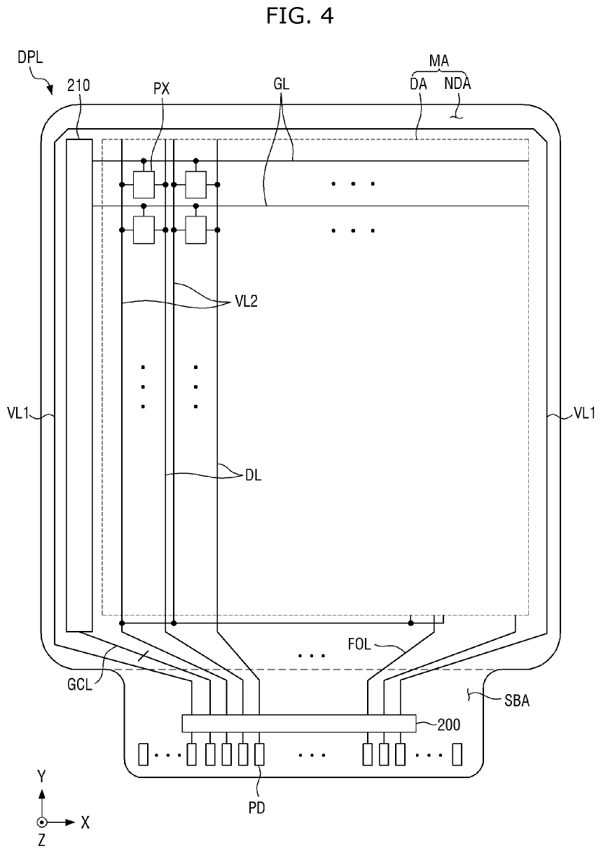

FIG. 4 is a schematic plan view of the display layer DPL in FIG. 3.

Referring to FIG. 4, the display layer DPL in the embodiment may include a plurality of pixels PX overlapping with the display area DA of the main area MA, a plurality of gate lines GL, a plurality of data lines DL, and a plurality of second voltage lines VL2.

Each of the plurality of pixels PX may be defined as the minimum unit that outputs light. The pixels PX may form emission areas EA1, EA2 and EA3, which will be described later.

The plurality of gate lines GL may supply the gate signals received from the gate driver 210 to the plurality of pixels PX. The plurality of gate lines GL may be extended in the first direction (x-axis direction) and may be spaced apart from each other in the second direction (y-axis direction) crossing the first direction (x-axis direction).

The plurality of data lines DL may supply the data voltages received from the display driver 200 to the plurality of pixels PX. The plurality of data lines DL may be extended in the second direction (y-axis direction) and may be spaced apart from each other in the first direction (x-axis direction).

The second voltage lines VL2 may apply the supply voltage received from the display driver 200 to the plurality of pixels PX. The supply voltage may be at least one of a driving voltage, an initialization voltage, and a reference voltage. The plurality of second voltage lines VL2 may be extended in the second direction (y-axis direction) and may be spaced apart from each other in the first direction (x-axis direction).

The display layer DPL in the embodiment may overlap with the non-display area NDA of the main area MA and may include a first voltage line VL1, a gate driver 210, a plurality of fan-out lines FOL, and a gate control line GCL.

The gate driver 210 may generate a plurality of gate signals based on the gate control signal, and may sequentially supply the plurality of gate signals to the plurality of gate lines GL in a predetermined order.

The first voltage line VL1 may surround the display area DA and may be disposed in the non-display area NDA. The first voltage line VL1 may apply the supply voltage received from the display driver 200 to the plurality of pixels PX. In addition, the first voltage line VL1 may be electrically connected to a variety of lines disposed in the display area DA.

The fan-out lines FOL may be extended from the display driver 200 to the display area DA. The fan-out lines FOL may supply the data voltage received from the display driver 200 to the plurality of data lines DL.

A gate control line GCL may be extended from the display driver 200 to the gate driver 210. The gate control line GCL may supply the gate control signal received from the display driver 200 to the gate driver 210. Although the gate driver 210 is disposed only in the non-display area NDA on the left side of the display area DA in the drawings, the disclosure is not limited thereto. In another embodiment, the display device 10 may include a plurality of gate drivers 210 disposed on the left and right sides of the display area DA, respectively.

The display layer DPL in the embodiment may overlap with the subsidiary area SBA and may include the display driver 200 and a plurality of display pads PD.

The display driver 200 may output signals and voltages for driving the pixels PX to the fan-out lines FOL. The display driver 200 may supply data voltages to the data lines DL through the fan-out lines FOL. By doing so, the data voltages may be applied to the pixels PX, so that the luminance of the pixels PX may be controlled. In addition, the display driver 200 may supply a gate control signal to the gate driver 210 through the gate control line GCL.

The plurality of display pads DP may be connected to a graphic system through the circuit board 300. The plurality of display pads DP may be connected to the circuit board 300 to receive digital video data and may supply the digital video data to the display driver 200.

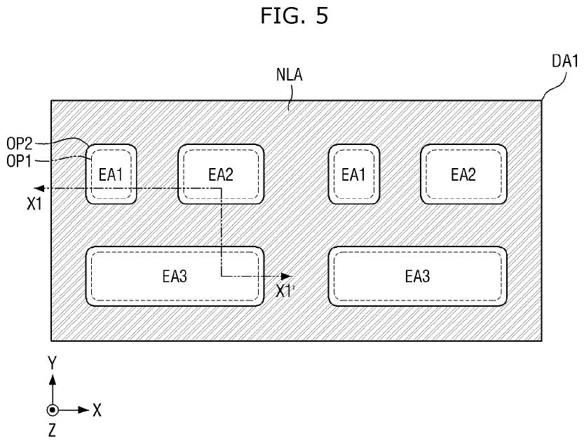

FIG. 5 is a plan view showing a layout of a plurality of emission areas EA1, EA2 and EA3 in the first display area DA1 of FIG. 2.

Referring to FIG. 5, the first display area DA1 may include a plurality of emission areas EA1, EA2 and EA3 and a non-emission area NLA. The non-emission area NLA may be disposed such that it surrounds the plurality of emission areas EA1, EA2 and EA3.

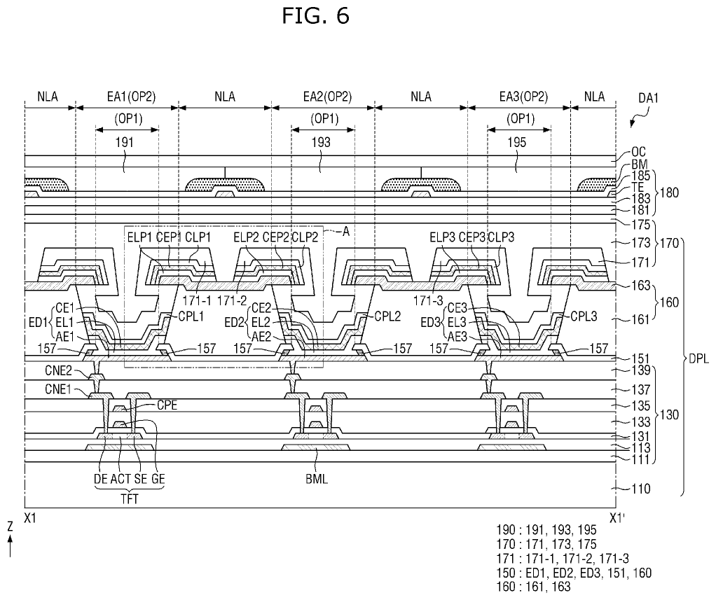

The non-emission area NLA may help prevent the lights exiting from the plurality of emission areas EA1, EA2 and EA3 from being mixed. In the non-emission area NLA, an inorganic pixel-defining layer 151 (refer to FIG. 6), a bank structure 160 (refer to FIG. 6), and a light-blocking layer BM may be disposed, which will be described later. That is to say, the non-emission area NLA may include a light-blocking function.

The emission areas EA1, EA2 and EA3 may include first emission areas EA1, second emission areas EA2 and third emission areas EA3 that emit lights of different colors. Each of the emission areas EA1, EA2 and EA3 may emit red, green or blue light. The colors of lights emitted from the emission areas EA1, EA2 and EA3 may vary depending on the type of light-emitting elements ED1, ED2 and ED3, which will be described later. In an embodiment of the disclosure, the first emission area EA1 may emit light of a first color, i.e., red light, the second emission area EA2 may emit light of a second color, i.e., green color, and the third emission area EA3 may emit light of a third color, i.e., blue color. It should be understood, however, that the disclosure is not limited thereto.

The first emission area EA1 and the second emission area EA2 may be disposed adjacent to each other in the first direction (x-axis direction). The first emission area EA1 and the second emission area EA2 may be disposed alternately in the first direction (x-axis direction). The plurality of third emission areas EA3 may be disposed adjacent to one another in the first direction (x-axis direction). The third emission areas EA3 may be spaced apart from the first emission areas EA1 and the second emission areas EA2 in the second direction (y-axis direction). Although the first emission areas EA1 are the smallest and the third emission areas EA3 are the largest in the drawings, the disclosure is not limited thereto. The sizes and shapes of the plurality of emission areas EA1, EA2 and EA3 may be adjusted as desired according to desired characteristics.

The emission areas EA1, EA2 and EA3 may be defined by first openings OP1 and second openings OP2. In an embodiment, the first openings OP1 may be defined by the inorganic pixel-defining layer 151 (refer to FIG. 6), and the second openings OP2 may be defined by the bank structure 160 (refer to FIG. 6), for example, which will be described later. The second openings OP2 may surround an entirety of the first openings OP1 in a plan view.

FIG. 6 is a schematic cross-sectional view of the first display area, taken along line X1-X1′ of FIG. 5.

FIG. 6 is a cross-sectional view of a part of the display device 10 in the first display area DA1, showing the cross sections of the substrate 110, the thin-film transistor layer 130, the display element layer 150, the thin-film encapsulation layer 170, the touch sensor layer 180 and the color filter layer 190. The substrate 110 has been described above with reference to FIG. 3; and, therefore, the redundant descriptions will be omitted.

Referring to FIG. 6, the thin-film transistor layer 130 may be disposed on the substrate 110. The thin-film transistor layer 130 may include a first buffer layer 111, a bottom metal layer BML, a second buffer layer 113, a thin-film transistor TFT, a gate insulator 131, a first inter-dielectric layer 133, a capacitor electrode CPE, a second inter-dielectric layer 135, a first connection electrode CNE1, a first via layer 137, a second connection electrode CNE2 and a second via layer 139.

The first buffer layer 111 may be disposed on the substrate 110. The first buffer layer 111 may include an inorganic film capable of preventing permeation of air or moisture. In an embodiment, the first buffer layer 111 may include a plurality of inorganic films stacked on one another alternately, for example.

The bottom metal layer BML may be disposed on the first buffer layer 111. In an embodiment, the bottom metal layer BML may be made up of a single layer or multiple layers of one of molybdenum (Mo), aluminum (Al), chromium (Cr), gold (Au), titanium (Ti), nickel (Ni), neodymium (Nd) and copper (Cu) or any alloys thereof, for example.

The second buffer layer 113 may cover the first buffer layer 111 and the bottom metal layer BML. The second buffer layer 113 may include an inorganic film capable of preventing permeation of air or moisture. In an embodiment, the second buffer layer 113 may include a plurality of inorganic films stacked on one another alternately, for example.

The thin-film transistor TFT may be disposed on the second buffer layer 113 and may form a pixel circuit connected to each of a plurality of pixels. In an embodiment, the thin-film transistor TFT may be a driving transistor or a switching transistor of the pixel circuit, for example. The thin-film transistor TFT may include an active layer ACT, a source electrode SE, a drain electrode DE and a gate electrode GE.

The active layer ACT may be disposed on the second buffer layer 113. The active layer ACT may overlap the bottom metal layer BML and the gate electrode GE in the thickness direction and may be insulated from the gate electrode GE by the gate insulator 131. The material of a part of the active layer ACT may be made conductive to form the source electrode SE and the drain electrode DE.

The gate electrode GE may be disposed on the gate insulator 131. The gate electrode GE may overlap the active layer ACT with the gate insulator 131 interposed therebetween.

The gate insulator 131 may be disposed over the active layer ACT. In an embodiment, the gate insulator 131 may cover the active layer ACT and the second buffer layer 113, and may insulate the active layer ACT from the gate electrode GE, for example. A contact hole through which the first connection electrode CNE1 passes may be defined in the gate insulator 131.

The first inter-dielectric layer 133 may cover the gate electrode GE and the gate insulator 131. A contact hole through which the first connection electrode CNE1 passes may be defined in the first inter-dielectric layer 133. The contact hole of the first inter-dielectric layer 133 may be extended to the contact hole of the gate insulator (hereinafter, also referred to as a gate insulating layer) 131 and a contact hole of the second inter-dielectric layer 135.

The capacitor electrode CPE may be disposed on the first inter-dielectric layer 133. The capacitor electrode CPE may overlap with the gate electrode GE in the thickness direction. The capacitor electrode CPE and the gate electrode GE may form a capacitance.

The second inter-dielectric layer 135 may cover the capacitor electrode CPE and the first inter-dielectric layer 133. A contact hole through which the first connection electrode CNE1 passes may be defined in the second inter-dielectric layer 135. The contact hole of the second inter-dielectric layer 135 may be extended to the contact hole of the first inter-dielectric layer 133 and the contact hole of the gate insulating layer 131.

The first connection electrode CNE1 may be disposed on the second inter-dielectric layer 135. The first connection electrode CNE1 may electrically connect the drain electrode DE of the thin-film transistor TFT with the second connection electrode CNE2. The first connection electrode CNE1 may be inserted into a contact hole defined in the second inter-dielectric layer 135, the first inter-dielectric layer 133 and the gate insulator 133 to contact the drain electrode DE of the thin-film transistor TFT.

The first via layer 137 may cover the first connection electrode CNE1 and the second inter-dielectric layer 135. The first via layer 137 may provide a flat surface over the underlying structures. A contact hole through which the second connection electrode CNE2 passes may be defined in the first via layer 137.

The second connection electrode CNE2 may be disposed on the first via layer 137. The second connection electrode CNE2 may electrically connect the first connection electrode CNE1 with the anode electrodes AE1, AE2 and AE3. The second connection electrode CNE2 may be inserted into a contact hole defined in the first via layer 137 to contact the first connection electrode CNE1.

The second via layer 139 may cover the second connection electrode CNE2 and the first via layer 137. Contact holes through which the anode electrodes AE1, AE2 and AE3 penetrates may be defined in the second via layer 139.

The display element layer 150 may be disposed on the thin-film transistor layer 130. The display element layer 150 may include the light-emitting elements ED1, ED2 and ED3, capping layers CPL1, CPL2 and CPL3, an inorganic pixel-defining layer 151, and a bank structure 160.

The light-emitting elements ED1, ED2 and ED3 may include anode electrodes AE1, AE2 and AE3, emissive layers EL1, EL2 and EL3, and cathode electrodes CE1, CE2 and CE3. The light-emitting elements ED1, ED2 and ED3 may include a first light-emitting element ED1 disposed in the first emission area EA1, a second light-emitting element ED2 disposed in the second emission area EA2, and a third light-emitting element ED3 disposed in the third emission area EA3.

The light-emitting elements ED1, ED2 and ED3 overlapping with the respective emission areas EA1, EA2 and EA3 may emit lights of different colors depending on the materials of the emissive layers EL1, EL2 and EL3. In an embodiment, the first light-emitting element EDI may emit light of the first color, i.e., red light, the second light-emitting element ED2 may emit light of the second color, i.e., green light, and the third light-emitting element ED3 may emit light of the third color, i.e., blue light, for example.

The anode electrodes AE1, AE2 and AE3 may be disposed on the second via layer 139. The anode electrodes AE1, AE2 and AE3 may be electrically connected to the drain electrode DE of the thin-film transistor TFT through the first and second connection electrodes CNE1 and CNE2.

The anode electrodes AE1, AE2 and AE3 may include a first anode electrode AE1 disposed in the first emission area EA1, a second anode electrode AE2 disposed in the second emission area EA2, and a third anode electrode AE3 disposed in the third emission area EA3. The first anode electrode AE1, the second anode electrode AE2 and the third anode electrode AE3 may be spaced apart from one another on the second via layer 139.

In an embodiment of the disclosure, the anode electrodes AE1, AE2 and AE3 may have a stack structure of a material layer having a relatively high work function such as indium-tin-oxide (“ITO”), indium-zinc-oxide (“IZO”), zinc oxide (ZnO) and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or any combinations thereof. In an embodiment, the anode electrodes AE1, AE2 and AE3 may have, but is not limited to, a multilayer structure of ITO/Mg, ITO/MgF, ITO/Ag, and ITO/Ag/ITO, for example.

The inorganic pixel-defining layer 151 may be disposed on the second via layer 139 and the anode electrodes AE1, AE2 and AE3. As described above, the inorganic pixel-defining layer 151 may define a plurality of first openings OP1 forming a plurality of emission areas EA1, EA2 and EA3. The inorganic pixel-defining layer 151 may be disposed on the entirety of the surface of the second via layer 139, and may expose parts of the upper surfaces of the anode electrodes AE1, AE2 and AE3. In an embodiment, the inorganic pixel-defining layer 151 may expose the anode electrodes AE1, AE2 and AE3 where it overlaps with the first openings OP1, and the emissive layers EL1, EL2 and EL3 may be disposed directly on the anode electrodes AE1, AE2 and AE3 in the first openings OP1, for example.

The inorganic pixel-defining layer 151 may include an inorganic insulating material. In an embodiment, the inorganic pixel-defining layer 151 may include aluminum oxide, titanium oxide, tantalum oxide, hafnium oxide, zinc oxide, silicon oxide, silicon nitride, and silicon oxynitride, for example.

The bank structure 160 may be disposed on the inorganic pixel-defining layer (also referred to as an inorganic pixel-defining film) 151. The bank structure 160 may define a plurality of second openings OP2 forming a plurality of emission areas EA1, EA2 and EA3. The light-emitting elements ED1, ED2 and ED3 of the display device 10 may be disposed to overlap with the second openings OP2 of the bank structure 160. The bank structure 160 may include a first bank layer 161 and a second bank layer 163 that include different metal materials and structures to perform different functions. The bank structure 160 will be described in detail later.

The emissive layers EL1, EL2 and EL3 may be disposed on the anode electrodes AE1, AE2 and AE3. The emissive layers EL1, EL2 and EL3 may be organic emissive layers including or consisting of organic materials and may be formed on the anode electrodes AE1, AE2 and AE3 via a deposition process. When the thin-film transistor TFT applies a predetermined voltage to the anode electrodes AE1, AE2 and AE3 and the cathode electrodes CE1, CE2 and CE3 receives a common voltage or cathode voltage, the holes and electrons may move to the emissive layers EL1, EL2 and EL3 through the hole transporting layer and the electron transporting layer, respectively, and they combine in the emissive layers EL1, EL2 and EL3 to emit light.

The emissive layers EL1, EL2 and EL3 may include a first emissive layer EL1, a second emissive layer EL2, and a third emissive layer EL3 disposed in the respective emission areas EA1, EA2 and EA3. In an embodiment, the first emissive layer EL1 may emit red light of the first color, the second emissive layer EL2 may emit green light of the second color, and the third emissive layer EL3 may emit blue light of the third color, for example. It should be understood, however, that the disclosure is not limited thereto.

In some embodiments, the anode electrodes AE1, AE2 and AE3 and the inorganic pixel-defining layer 151 may be spaced apart from each other in the third direction (z-axis direction). The emissive layers EL1, EL2 and EL3 and the remaining patterns 157 may be disposed where the anode electrodes AE1, AE2 and AE3 are spaced apart from the inorganic pixel-defining layer 151. This will be described in detail later.

The cathode electrodes CE1, CE2 and CE3 may be disposed on the emissive layers EL1, EL2 and EL3, respectively. The cathode electrodes CE1, CE2 and CE3 include a transparent conductive material to allow lights generated in the emissive layers EL1, EL2 and EL3 to exit. The cathode electrodes CE1, CE2 and CE3 may receive a common voltage or a low-level voltage. When the anode electrodes AE1, AE2 and AE3 receive the voltage equal to the data voltage and the cathode electrodes CE1, CE2 and CE3 receive the low-level voltage, a potential difference may be formed between the anode electrodes AE1, AE2 and AE3 and the cathode electrodes CE1, CE2 and CE3, so that the emissive layers EL1, EL2 and EL3 may emit lights.

In an embodiment of the disclosure, the cathode electrodes CE1, CE2 and CE3 may include a material layer having a relatively small work function such as Li, Ca, LiF/Ca, LiF/Al, Al, Mg, Ag, Pt, Pd, Ni, Au, Nd, Ir, Cr, BaF and Ba, or a compound or combination thereof (e.g., a combination of Ag and Mg). The cathode electrodes CE1, CE2 and CE3 may further include a transparent metal oxide layer disposed on the material layer having a relatively small work function.

The cathode electrodes CE1, CE2 and CE3 may include a first cathode electrode CE1, a second cathode electrode CE2 and a third cathode electrode CE3 disposed in the emission areas EA1, EA2 and EA3, respectively. The first cathode electrode CE1 may be disposed on the first emissive layer EL1 in the first emission area EA1, the second cathode electrode CE2 may be disposed on the second emissive layer EL2 in the second emission area EA2, and the third cathode electrode CE3 may be disposed on the third emissive layer EL3 in the third emission area EA3.

The cathode electrodes CE1, CE2 and CE3 disclosed herein may be disposed in line with the respective emission areas EA1, EA2 and EA3 and may be spaced apart from one another. The cathode electrodes CE1, CE2 and CE3 disclosed herein may be electrically connected with one another not directly but through the first bank layer 161 of the bank structure 160.

The capping layers CPL1, CPL2 and CPL3 may be disposed on the cathode electrodes CE1, CE2 and CE3. The capping layers CPL1, CPL2 and CPL3 may include an inorganic insulating material to cover the light-emitting elements ED1, ED2 and ED3 and patterns disposed on the bank structure 160. The capping layers CPL1, CPL2 and CPL3 may prevent the light-emitting elements ED1, ED2 and ED3 from being damaged by outside air and may prevent the patterns disposed on the bank structure 160 from being delaminated during the process of fabricating the display device 10. In an embodiment, the capping layers CPL1, CPL2 and CPL3 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O), for example.

The capping layers CPL1, CPL2 and CPL3 may include a first capping layer CPL1, a second capping layer CPL2 and a third capping layer CPL3 disposed in the respective emission areas EA1, EA2 and EA3. The first capping layer CPL1 may be disposed on the first cathode electrode CE1 in the first emission area EA1, the second capping layer CPL2 may be disposed on the second cathode electrode CE2 in the second emission area EA2, and the third capping layer CPL3 may be disposed on the third cathode electrode CE3 in the third emission area EA3. That is to say, the capping layers CPL1, CPL2 and CPL3 may overlap with the emission areas EA1, EA2 and EA3 and spaced apart from one another.

As shown in FIG. 6, a plurality of organic patterns ELP1, ELP2 and ELP3, electrode patterns CEP1, CEP2 and CEP3, and capping patterns CLP1, CLP2 and CLP3 may be disposed on the bank structure 160 to surround the first opening OP1. The plurality of organic patterns ELP1, ELP2 and ELP3, the electrode patterns CEP1, CEP2 and CEP3, and the capping patterns CLP1, CLP2 and CLP3 may be partially etched during the process of fabricating the display device 10. Accordingly, the organic patterns ELP1, ELP2 and ELP3, the electrode patterns CEP1, CEP2 and CEP3, and the capping patterns CLP1, CLP2 and CLP3 may overlap with the non-emission area NLA and may be spaced apart from one another.

The organic patterns ELP1, ELP2 and ELP3 may be disposed on the second bank layer 163. The organic patterns ELP1, ELP2 and ELP3 may include the same materials as the emissive layers EL1, EL2 and EL3, respectively. The first organic pattern ELP1 may include the same material as that of the first emissive layer EL1, the second organic pattern ELP2 may include the same material as that of the second emissive layer EL2, and the third organic pattern ELP3 may include the same material as that of the third emissive layer EL3. The organic patterns ELP1, ELP2 and ELP3 may be formed as traces that are disconnected from the emissive layers EL1, EL2 and EL3 as the bank structure 160 includes the tip TIP. The tip included in the bank structure 160 will be described in detail later.

The electrode patterns CEP1, CEP2 and CEP3 may be disposed on the organic patterns ELP1, ELP2 and ELP3, respectively. In an embodiment, the first electrode pattern CEP1, the second electrode pattern CEP2 and the third electrode pattern CEP3 may be disposed directly on the first organic pattern ELP1, the second organic pattern ELP2 and the third organic pattern ELP3, respectively, for example. The arrangement relationship between the electrode patterns CEP1, CEP2 and CEP3 and the organic patterns ELP1, ELP2 and ELP3 may be identical to the arrangement relationship between the emissive layers EL1, EL2 and EL3 and the cathode electrodes CE1, CE2 and CE3. The electrode patterns CEP1, CEP2 and CEP3 may include the same materials as the cathode electrodes CE1, CE2 and CE3, respectively. The electrode patterns CEP1, CEP2 and CEP3 may be traces that are formed as they are disconnected from the cathode electrodes CE1, CE2 and CE3 since the bank structure 160 includes the tip TIP. The tip included in the bank structure 160 will be described in detail later.

The capping patterns CLP1, CLP2 and CLP3 may be disposed on the electrode patterns CEP1, CEP2 and CEP3, respectively. The capping patterns CLP1, CLP2 and CLP3 may include the same material as that of the capping layers CPL1, CPL2 and CPL3. The arrangement relationship between the capping patterns CLP1, CLP2 and CLP3 and the electrode patterns CEP1, CEP2 and CEP3 may be identical to the arrangement relationship between the capping layers CPL1, CPL2 and CPL3 and the cathode electrodes CE1, CE2 and CE3. The capping patterns CLP1, CLP2 and CLP3 may be traces that are formed as they are disconnected from the cathode electrodes CE1, CE2 and CE3 since the bank structure 160 includes the tip TIP. The tip included in the bank structure 160 will be described in detail later.

The thin-film encapsulation layer 170 may be disposed on the capping layers CPL1, CPL2 and CPL3 and the capping patterns CLP1, CLP2 and CLP3 to cover the capping layers CPL1, CPL2 and CPL3 and the capping patterns CLP1, CLP2 and CLP3.

The thin-film encapsulation layer 170 may include at least one inorganic film to prevent permeation of oxygen or moisture into the display element layer 150. The thin-film encapsulation layer 170 may include at least one organic film to protect the display element layer 150 from foreign substances such as dust.

In an embodiment of the disclosure, the thin-film encapsulation layer 170 may include a first encapsulation layer 171, a second encapsulation layer 173, and a third encapsulation layer 175 sequentially stacked on one another. The first encapsulation layer 171 and the third encapsulation layer 175 may be inorganic encapsulation layers, and the second encapsulation layer 173 disposed therebetween may be an organic encapsulation layer.

Each of the first encapsulation layer 171 and the third encapsulation layer 175 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may include a polymer-based material. The polymer-based material may include an acrylic resin, an epoxy resin, polyimide, polyethylene, etc. In an embodiment, the second encapsulation layer 173 may include an acrylic resin, e.g., polymethyl methacrylate, polyacrylic acid, etc., for example. The second encapsulation layer 173 may be formed by curing a monomer or by applying a polymer.

The first encapsulation layer 171 may include first to third inorganic layers 171-1, 171-2 and 171-3. The first to third inorganic layers 171-1, 171-2 and 171-3 may be disposed to cover the capping layers CPL1, CPL2 and CPL3, the capping patterns CLP1, CLP2 and CLP3, and the bank structure 160. Since the first to third inorganic layers 171-1, 171-2 and 171-3 may be formed via a chemical vapor deposition (“CVD”) process, they may be formed to have a uniform thickness along the profile of the underlying structures.

The first to third inorganic layers 171-1, 171-2 and 171-3 may be disposed to overlap with of the respective emission areas EA1, EA2 and EA3. In an embodiment, the first inorganic layer 171-1 may overlap with the first emission area EA1 and cover the first capping layer CPL1 and the first capping pattern CLP1, for example. In addition, the second inorganic layer 171-2 may overlap with the second emission area EA2 and cover the second capping layer CPL2 and the second capping pattern CLP2. In addition, the third inorganic layer 171-3 may overlap with the third emission area EA3 and cover the third capping layer CPL3 and the third capping pattern CLP3. The first to third inorganic layers 171-1, 171-2 and 171-3 may overlap the non-emission area NLA to expose the bank structure 160 and may be spaced apart from one another.

Although the first to third inorganic layers 171-1, 171-2 and 171-3 are formed in the same layer in the drawings, the first to third inorganic layers 171-1, 171-2 and 171-3 may be formed in different processes. In an embodiment, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed, for example. The process of fabricating the first to third inorganic layers 171-1, 171-2 and 171-3 will be described in detail later.

The touch sensor layer 180 may be disposed on the thin-film encapsulation layer 170. The touch sensor layer 180 may include a touch buffer layer 181, a touch insulating layer 183, touch electrodes TE, and a touch protective layer 185.

The touch buffer layer 181 may be disposed on the thin-film encapsulation layer 170. The touch buffer layer 181 may be insulating and optical functions. The touch buffer layer 181 may include at least one inorganic film. Optionally, the touch buffer layer 181 may be eliminated.

Although not shown in the drawings, the connection electrodes electrically connecting between the touch electrodes may be disposed on the touch buffer layer 181. The connection electrodes may be made up of a single layer of molybdenum (Mo), titanium (Ti), copper (Cu), aluminum (Al), or indium tin oxide (“ITO”), or may be made up of a stack structure of aluminum and titanium (Ti/Al/Ti), a stack structure of aluminum and ITO (“ITO/Al/ITO”), an APC alloy and a stack structure of an APC alloy and ITO (“ITO/APC/ITO”).

The touch insulating layer 183 may cover the touch buffer layer 181. The touch insulating layer 183 may have insulating and optical functions. In an embodiment, the touch insulating layer 183 may be an inorganic layer including at least one selected from the group including: a silicon nitride layer, a silicon oxynitride layer, a silicon oxide layer, a titanium oxide layer and an aluminum oxide layer, for example.

Some of the touch electrodes TE may be disposed on the touch insulating layer 183. Each of the touch electrodes TE may not overlap with the plurality of emission areas EA1, EA2 and EA3 but may be disposed in the non-emission area NLA. The touch electrodes TE may be made up of a single layer of molybdenum (Mo), titanium (Ti), copper (Cu), aluminum (Al), or indium tin oxide (“ITO”), or may be made up of a stack structure of aluminum and titanium (Ti/Al/Ti), a stack structure of ITO/Al/ITO, an APC alloy and a stack structure of ITO/APC/ITO.

The touch protective layer 185 may cover the touch electrodes TE and the touch insulating layer 183. The touch protective layer 185 may have insulating and optical functions. The touch protective layer 185 may include or consist of any of the above-listed materials as embodiments of the touch insulating layer 183.

The light-blocking layer BM may be disposed on the touch sensor layer 180. The light-blocking layer BM may be disposed in the non-emission area NLA to overlap with the inorganic pixel-defining layer 151 and the bank structure 160.

The light-blocking layer BM may include a light-absorbing material. In an embodiment, the light-blocking layer BM may include an inorganic black pigment or an organic black pigment, for example. The inorganic black pigment may be, but is not limited to, carbon black, and the organic black pigment may include, but is not limited to, at least one of lactam black, perylene black, and aniline black. The light-blocking layer BM may prevent visible light from penetrating and mixing colors between the emission areas EA1, EA2 and EA3 to improve the color gamut of the display device 10.

The color filter layer 190 may overlap with the emission areas EA1, EA2 and EA3 and may be disposed on the touch protective layer 185 and the light-blocking layer BM.

The color filter layer 190 may include a first color filter 191, a second color filter 193 and a third color filter 195 disposed in the emission areas EA1, EA2 and EA3, respectively. The color filters 191, 193 and 195 in line with the respective emission areas EA1, EA2 and EA3 may include colorants such as a dye and pigment that absorb lights in wavelength ranges other than light in a particular wavelength range, and may be associated with the lights exiting from the emission areas EA1, EA2 and EA3. In an embodiment, the first color filter 191 may be a red color filter that is disposed to overlap with the first emission area EA1 and transmits only the light of the first color, i.e., the red light, for example. The second color filter 193 may be a green color filter that is disposed to overlap with the second emission area EA2 and transmits only the light of the second color, i.e., the green light. The third color filter 195 may be a blue color filter that is disposed to overlap with the third emission area EA3 and transmits only the light of the third color, i.e., the blue light. It should be understood, however, that the disclosure is not limited thereto.

The overcoat layer OC may be disposed over the color filter layer 190 and the light-blocking layer BM to provide a flat surface over the color filter layer 190. The overcoat layer OC may be a colorless light-transmitting layer having no color in the visible light band. In an embodiment, the overcoat layer OC may include a colorless light-transmitting organic material such as an acryl-based resin, for example.

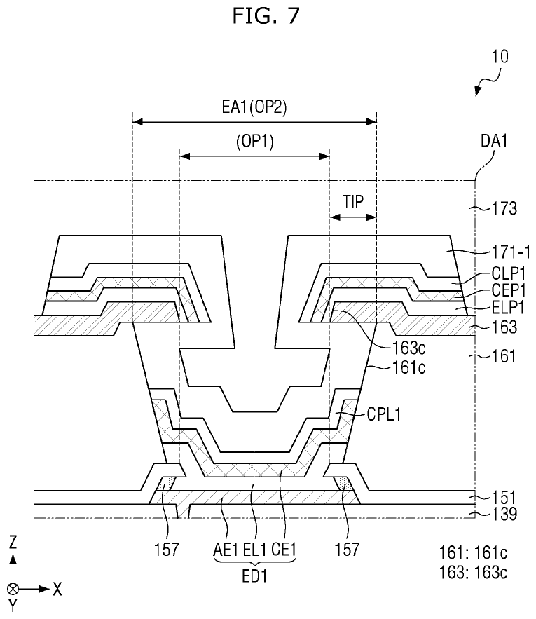

FIG. 7 is an enlarged cross-sectional view of the first emission area EA1 in FIG. 6.

Referring to FIG. 7, the inorganic pixel-defining layer 151 may be disposed on the second via layer 139 and the first anode electrode AE1. The inorganic pixel-defining layer 151 may be in line with the second opening OP2 and may be spaced apart from the first anode electrode AE1 in the third direction (z-axis direction). A remaining pattern 157 may be disposed between the inorganic pixel-defining layer 151 and the first anode electrode AE1.

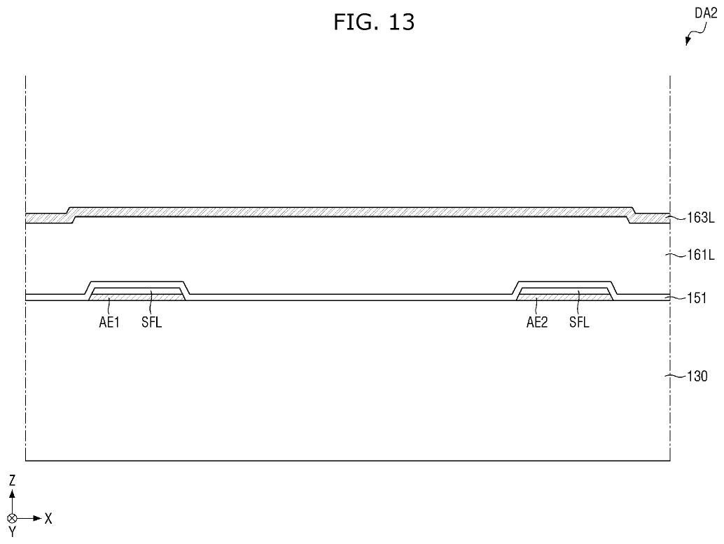

The display device 10 may include a sacrificial layer SFL (refer to FIG. 13) between the inorganic pixel-defining layer 151 and the anode electrodes AE1, AE2 and AE3 during the fabrication process. The sacrificial layer SFL may be disposed between the inorganic pixel-defining layer 151 and the anode electrodes AE1, AE2 and AE3, and then partially removed via a subsequent wet etching process. A portion of the sacrificial layer SFL that has not been removed may remain as the remaining pattern 157 between the inorganic pixel-defining layer 151 and the anode electrodes AE1, AE2 and AE3. The fabrication process will be described in detail later.

The bank structure 160 may include a first bank layer 161 and a second bank layer 163 that include different metal materials and structures to perform different functions. The first bank layer 161 may be disposed on the inorganic pixel-defining layer 151.

The first bank layer 161 may electrically connect the cathode electrodes CE1, CE2 and CE3 disposed in the emission areas EA1, EA2 and EA3, respectively. The first bank layer 161 may include a metal with relatively high electrical conductivity. In an embodiment, the first bank layer 161 may include aluminum (Al), for example. The thickness of the first bank layer 161 in the third direction (z-axis direction) may range from, but is not limited to, about 0.3 micrometer (um) to about 1.0 μm.

In some embodiments, the first bank layer 161 may include a side surface 161c facing the first opening OP1. The side surface 161c of the first bank layer 161 may be an inclined surface. In other words, the side surface 161c of the first bank layer 161 may be inclined between the first direction (x-axis direction) and the third direction (z-axis direction). That is to say, the side surface 161c of the first bank layer 161 may include a structure that is more depressed in the first direction (x-axis direction) than the inorganic pixel-defining layer 151. This may be because the first bank layer 161 includes an etching process during the fabrication process. The process of fabricating the first bank layer 161 will be described in detail later.

The emissive layers EL1, EL2 and EL3, the cathode electrodes CE1, CE2 and CE3, and the capping layers CPL1, CPL2 and CPL3 may contact the side surface 161c of the first bank layer 161. As a result, the cathode electrodes CE1, CE2 and CE3 may be electrically connected to the first bank layer 161. The larger the contact area between the cathode electrodes CE1, CE2 and CE3 and the side surface 161c of the first bank layer 161 is, the lower the electrical resistance of the display device 10 may be, and the more stable the electrical characteristics of the display device 10 may be.

The second bank layer 163 may be disposed on the first bank layer 161. The second bank layer 163 may include a material having a lower etching rate than the first bank layer 161, and for example, the second bank layer 163 may include titanium (Ti).

In some embodiments, the second bank layer 163 may include a side surface 163c facing the first opening OP1. The side surface 163c of the second bank layer 163 may have a shape that protrudes toward the first opening OP1 further than the side surface 161c of the first bank layer 161. In other words, the side surface 161c of the first bank layer 161 may have a shape recessed from the side surface 163c of the second bank layer 163 in the first direction (x-axis direction). Accordingly, the second bank layer 163 may include a tip TIP protruding toward the first opening OP1, and an undercut may be formed between the tip TIP of the second bank layer 163 and the side surface 161c of the first bank layer 161.

Typically, high-resolution display devices may desire relatively high pixel density. In other words, a high-resolution display device may have narrow spacing between adjacent light-emitting elements ED1, ED2 and ED3. Therefore, it may be difficult to form the plurality of light-emitting elements ED1, ED2 and ED3 included in the high-resolution display device using a mask during the fabrication process.

In the display device 10 disclosed herein, the second bank layer 163 includes protruding tips, so that the light-emitting elements ED1, ED2 and ED3 in line with the emission areas EA1, EA2 and EA3 may be formed even without a mask during the process of fabricating the display device 10. The process of fabricating the light-emitting elements ED1, ED2 and ED3 and the second bank layer 163 disclosed herein will be described in detail later.

As described above, the first emissive layer EL1 may contact the first anode electrode AE1 in the first opening OP1, and may contact the side surface 161c of the first bank layer 161 in the second opening OP2. In addition, the first emissive layer EL1 may be also disposed where the first anode electrode AE1 and the inorganic pixel-defining layer 151 spaced apart from each other in the third direction (z-axis direction). This may be because the material for forming the emissive layers EL1, EL2 and EL3 is deposited in an oblique direction rather than the vertical direction of the substrate 110 during the process of forming the emissive layers EL1, EL2 and EL3. This will be described later with the fabrication method. Although only the first emissive layer EL1 is described for convenience of illustration, the second emissive layer EL2 and the third emissive layer EL3 may have the same structure and features.

The first cathode electrode CE1 may be disposed on the first emissive layer EL1 in the first opening OP1, and may be disposed on the side surface 161c of the first bank layer 161 in the second opening OP2. The first cathode electrode CE1 may contact the first emissive layer EL1 in the first opening OP1, and may contact the side surface 161c of the first bank layer 161 in the second opening OP2.

The first cathode electrode CE1 may cover more the side surface 161c of the first bank layer 161 than the first emissive layer EL1. In other words, the first cathode electrode CE1 may cover an entirety of the first emissive layer EL1 on the side surface 161c of the first bank layer 161. This may occur because the angle at which the material forming the cathode electrodes CE1, CE2 and CE3 is deposited is closer to the substrate 100 than the angle at which the material forming the emissive layers EL1, EL2 and EL3 is deposited in the process of forming the cathode electrodes CE1, CE2 and CE3. This will be described later with the fabrication method. Although only the first cathode electrode CE1 is described for convenience of illustration, the second cathode electrode CE2 and the third cathode electrode CE3 may have the same structure and features. The capping layers CPL1, CPL2 and CPL3 have been described above and thus will not be described again.

The first organic pattern ELP1 may be disposed on the second bank layer 163. The first organic pattern ELP1 may overlap with the protruding tip TIP of the second bank layer 163 and cover the side surface 163c of the second bank layer 163. In addition, the first electrode pattern CEP1 may be disposed on the first organic pattern ELP1. The first electrode pattern CEP1 may overlap with the protruding tip TIP of the second bank layer 163 and cover the side surface of the first organic pattern ELP1. That is to say, the first electrode pattern CEP1 may overlap the side surface 163c of the second bank layer 163 in the first direction (x-axis direction). In addition, the first capping pattern CLP1 may be disposed on the first electrode pattern CEP1. The first capping pattern CLP1 may overlap with the protruding tip TIP of the second bank layer 163 and cover the side surface of the first electrode pattern CEP1. That is to say, the first capping pattern CLP1 may overlap the side surface 163c of the second bank layer 163 in the first direction (x-axis direction).

The first inorganic layer 171-1 may be disposed on the first capping layer CPL1 and the first capping pattern CLP1. The first inorganic layer 171-1 in the second opening OP2 may cover an entirety of the first capping layer CPL1 and the first capping pattern CLP1 in the second opening OP2. The first inorganic layer 171-1 may contact the side surface 161c of the first bank layer 161 where the first capping layer CPL1 and the first capping pattern CLP1 are spaced apart from each other.

During the process of fabricating the display device 10, the first organic pattern ELP1, the first electrode pattern CEP1, the first capping pattern CLP1 and the first inorganic layer 171-1 may be partially removed via an etching process. Accordingly, portions of the first organic pattern ELP1, the first electrode pattern CEP1, the first capping pattern CLP1 and the first inorganic layer 171-1 may be exposed the outside of the first emission area EA1. The exposed portions of the first organic pattern ELP1, the first electrode pattern CEP1, the first capping pattern CLP1 and the first inorganic layer 171-1 may be covered by the second encapsulation layer 173, and may contact the second encapsulation layer 173. Although the first patterns ELP1, CEP1 and CLP1 and the first inorganic layer 171-1 disposed in and around the first emission area EA1 have been described for convenience of illustration, it is to be understood that the patterns and the first encapsulation layer 171 overlapping with the emission areas EA1, EA2 and EA3 and their peripheries may all include the same structure and features.

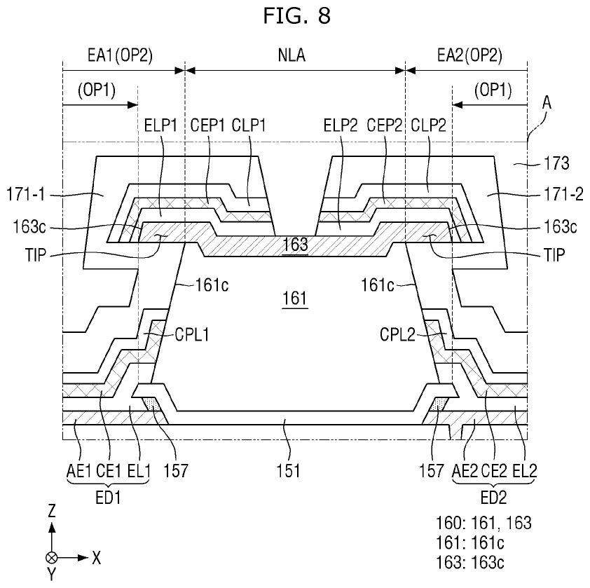

FIG. 8 is an enlarged, cross-sectional view of area A of FIG. 6.

Referring to FIG. 8, the first anode electrode AE1 and the second anode electrode AE2 may be spaced apart from each other by the inorganic pixel-defining layer 151. In addition, the bank structure 160 may be disposed on the inorganic pixel-defining layer 151, and the first bank layer 161 of the bank structure 160 may include two side surfaces 161c facing the first emission area EA1 and the second emission area EA2.

A second side surface 161c of the first bank layer 161 may overlap with the first emission area EA1 and may contact a first emissive layer EL1, a first cathode electrode CE1, a first capping layer CPL1, and a first inorganic layer 171-1. A first side surface 161c of the first bank layer 161 may overlap with the second emission area EA2 and may contact a second emissive layer EL2, a second cathode electrode CE2, a second capping layer CPL2, and a second inorganic layer 171-2. Accordingly, the first cathode electrode CE1 and the second cathode electrode CE2 may be electrically connected with each other through the first bank layer 161.

The second bank layer 163 of the bank structure 160 may include the two side surfaces 163c facing the first and second emission areas EA1 and EA2. The side surfaces 163c of the second bank layer 163 may protrude from the side surfaces 161c of the first bank layer 161. Therefore, the second bank layer 163 may include tips protruding further than the opposite sides of the side surfaces 161c of the first bank layer 161.

The first organic pattern ELP1, the first electrode pattern CEP1, the first capping pattern CLP1 and the first inorganic pattern. The first inorganic layers 171-1 may overlap with the protruding tip TIP of the second bank layer 163 that includes the second side surface 163c. In addition, the second organic pattern ELP2, the second electrode pattern CEP2, the second capping pattern CLP2 and the second inorganic layer 171-2 may overlap with the protruding tip TIP of the second bank layer 163 that includes the first side surface 163c.

In the non-emission area NLA, the first organic pattern ELP1, the first electrode pattern CEP1, the first capping pattern CLP1 and the first inorganic layer 171-1 may be spaced apart from the second organic pattern ELP2, the second electrode pattern CEP2, the second capping pattern CLP2 and the second inorganic layer 171-2 on the second bank layer 163. Accordingly, a portion of the second bank layer 163 may be exposed, and the exposed portion of the second bank layer 163 may contact the second encapsulation layer 173.

Although the structures overlapping with the first light-emitting element ED1 and the second light-emitting element ED2 are shown and described for convenience of illustration, the structures overlapping with a plurality of light-emitting elements ED1, ED2 and ED3 may include the same structure and features.

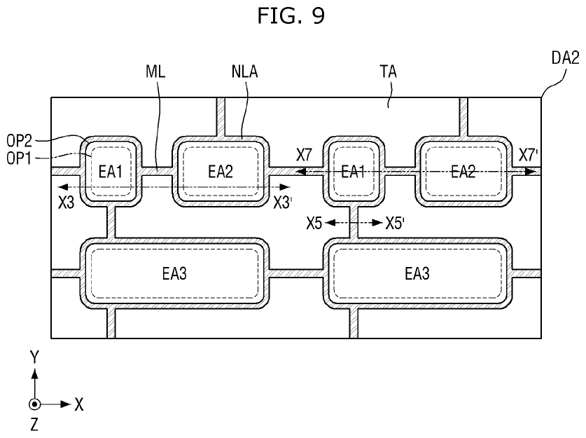

FIG. 9 is a plan view showing a layout of emission areas EA1, EA2 and EA3 in the second display area DA2 of FIG. 2.

Referring to FIG. 9, the second display area DA2 may include a transmissive area TA in addition to the plurality of emission areas EA1, EA2 and EA3 and the non-emission area NLA.

Each of the emission areas EA1, EA2 and EA3 may be defined by a first opening OP1 and a second opening OP2. In an embodiment, the first opening OP1 may be defined by the inorganic pixel-defining layer 151, and the second opening OP2 may be defined by the bank structure 160. In a plan view, the second opening OP2 may surround an entirety of the first opening OP1, like the first display area DA1.

The non-emission area NLA of the second display area DA2 may be similar to the first display area DA1 in that it surrounds the plurality of emission areas EA1, EA2 and EA3. However, the non-emission area NLA of the second display area DA2 may be different from the first display area DA1 in that it is surrounded by the transmissive area TA. In other words, the non-emission area NLA of the second display area DA2 may be disposed between the plurality of emission areas EA1, EA2 and EA3 and the transmissive area TA. The non-emission area NLA of the second display area DA2 may overlap with the bank structure 160.

The transmissive area TA of the second display area DA2 may transmit light, and an optical device may be disposed in line with the transmissive area TA of the display device 10. The transmissive area TA of the second display area DA2 may be defined by the protruding tip TIP of the bank structure 160 facing the transmissive area TA. This will be described later with the fabrication process.

The display device 10 in an embodiment may include a plurality of metal lines ML overlapping the transmissive area TA. The plurality of metal lines ML may electrically connect the cathode electrodes CE1, CE2 and CE3 overlapping the respective emission areas EA1, EA2 and EA3 in the second display area DA2. Accordingly, adjacent ones of the emission areas EA1, EA2 and EA3 may be connected with each other by a single metal line ML.

The metal lines ML are disposed in the transmissive area TA but do not transmit lights. Accordingly, a single metal line ML may be formed to maximize the transmissive area TA of the second display area DA2, and may be desired to have a width as narrow as possible.

The plurality of metal lines ML may be formed integrally with the bank structure 160 surrounding the emission areas EA1, EA2 and EA3. That is to say, the plurality of metal lines ML may be part of the bank structure 160 as the bank structure 160 in the non-emission area NLA is extended to the transmissive area TA. This will be described in detail later with the cross-sectional structure.

Although not shown in the drawings, the metal line ML connecting the of the emission areas EA1, EA2 and EA3 in the transmissive area TA of the display area DA may be connected to a first voltage line VL1 disposed in the non-display area NDA. In this manner, the display device 10 in the embodiment may be electrically stable.

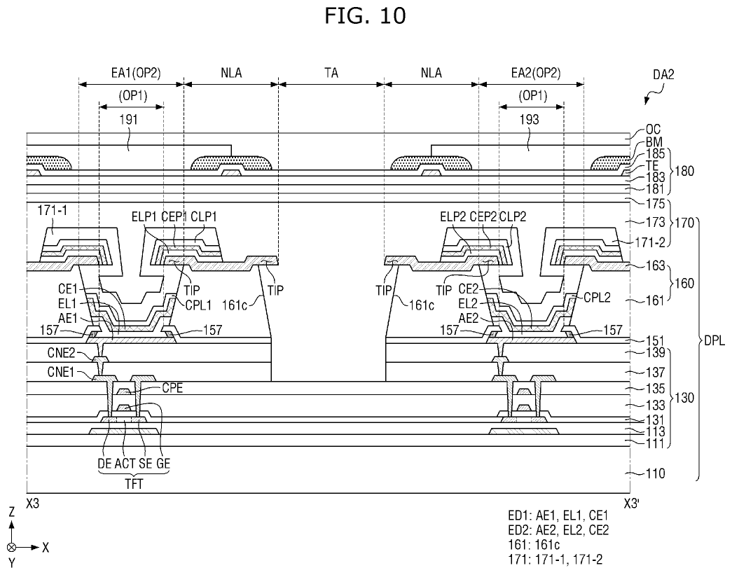

FIG. 10 is a cross-sectional view taken along line X3-X3′ of FIG. 9.

FIG. 10 is a cross-sectional view schematically showing the structure of the second display area DA2. The cross-sectional structure overlapping with the emission areas EA1, EA2 and EA3 is identical to that of the first display area DA1; and, therefore, the redundant descriptions will be omitted.

Referring to FIG. 10, in the second display area DA2, the thin-film transistor layer 130 may be disposed on the substrate 110 to overlap with the transmissive area TA. However, the thin-film transistor layer 130 in the transmissive area TA is different from the thin-film transistor layer 130 in the emission areas EA1, EA2 and EA3 in that the thin-film transistor TFT, the metal materials such as the first connection electrode CNE1 and the second connection electrode CNE2, and the organic material layers such as the second via layer 139 is not included.

In some embodiments, the thin-film transistor layer 130 overlapping the transmissive area TA may include a first buffer layer 111, a second buffer layer 113, a gate insulator 131, a first inter-dielectric layer 133, and a second inter-dielectric layer 135. It should be understood, however, that the disclosure is not limited thereto. The thin-film transistor layer 130 in the transmissive area TA may include any structure as long as it has transparency that does not lower light transmission. The elements have been described above and thus will not be described again.

The display device 10 in the embodiment does not include the display element layer 150 in the transmissive area TA. Specifically, the display device 10 may not include the light-emitting elements ED1, ED2 and ED3, the inorganic pixel-defining layer 151 or the bank structure 160 in the transmissive area TA. Accordingly, the thin-film encapsulation layer 170 may be disposed directly on the thin-film transistor layer 130.

The first encapsulation layer 171 of the display device 10 in the embodiment may be formed on the entirety of the surface of the plurality of emission areas EA1, EA2 and EA3 and the transmissive area TA during the fabrication process, and then may be removed during a subsequent etching process, leaving portions in the emission areas EA1, EA2 and EA3. Accordingly, the first encapsulation layer 171 may not overlap with the transmissive area TA.

It should be understood, however, that the disclosure is not limited thereto. The first encapsulation layer 171 may be disposed in line with the transmissive area TA depending on process conditions. When the first encapsulation layer 171 is disposed in line with the transmissive area TA, the first encapsulation layer 171 may cover along the profile of the underlying structures.

The second encapsulation layer 173 in line with the transmissive area TA may provide a flat surface over the underlying structures having different heights. Accordingly, the third encapsulation layer 175 in line with the transmissive area TA may be extended from the plurality of emission areas EA1, EA2 and EA3 and the non-emission area NLA to cover the transmissive area TA without any level difference. The second encapsulation layer 173 may have transparency within a range that does not lower light transmission.

The touch sensor layer 180 may be disposed on the thin-film encapsulation layer 170 in the transmissive area TA. The touch sensor layer 180 in the transmissive area TA may include a touch buffer layer 181, a touch insulating layer 183, and a touch protective layer 185. The touch buffer layer 181, the touch insulating layer 183 and the touch protective layer 185 may include transparency within a range that does not lower light transmission.

The display device 10 in the embodiment does not include the color filter layer 190 in the transmissive area TA. Accordingly, in the display device 10, the overcoat layer OC may be disposed on the touch sensor layer 180 in the transmissive area TA. The overcoat layer OC may provide a flat surface over the underlying structures have different heights. The overcoat layer OC may have transparency within a range that does not lower light transmission.

The display device 10 in the embodiment may include a plurality of non-emission areas NLA adjacent to the opposite sides of the transmissive area TA. The inorganic pixel-defining layer 151 may be disposed on the second via layer 139 in the non-emission area NLA. The display device 10 in the embodiment may be subjected to a process of etching portions of the first via layer 137, the second via layer 139, the inorganic pixel-defining layer 151 and the bank structure 160 in line with the transmissive area TA during the fabrication process. As a result, the first via layer 137, the second via layer 139, the inorganic pixel-defining layer 151 and the bank structure 160 in line with the transmissive area TA may be removed, and the side surfaces of the first via layer 137, the side surfaces of the second via layer 139 and the side surfaces of the inorganic pixel-defining layer 151 may have aligned cross-sections that face the transmissive area TA.

The bank structure 160 may be included on the inorganic pixel-defining layer 151 in the non-emission area NLA. The bank structure 160 may include a first bank layer 161 and a second bank layer 163. The second bank layer 163 may include a tip TIP protruding in the first direction (x-axis direction) from the first bank layer 161 toward the transmissive area TA, which is formed because the first bank layer 161 has a higher etch rate than the second bank layer 163.

The protruding tip TIP of the second bank layer 163 facing the transmissive area TA may not overlap with a plurality of patterns ELP1 to ELP3, CEP1 to CEP3 and CLP1 to CLP3. In other words, a plurality of organic patterns ELP1, ELP2 and ELP3, a plurality of electrode patterns CEP1, CEP2 and CEP3, or a plurality of capping patterns CLP1, CLP2 and CLP3 may not be disposed on the protruding tip TIP of the second bank layer 163 facing the transmissive area TA. This may be obtained because an etching process in the transmissive area TA is included in the fabrication process. A more detailed description thereon will be given later.

The protruding tip TIP of the second bank layer 163 facing the transmissive area TA in the non-emission area NLA of the second display area DA2 may be covered by the second encapsulation layer 173. As described above, since the patterns ELP1 to ELP3, CEP1 to CEP3 and CLP1 to CLP3 are not disposed on the second bank layer 163 facing the transmissive area TA, the protruding tip TIP of the second bank layer 163 protruding toward the transmissive area TA may contact the second encapsulation layer 173. In addition, the structure and characteristics of the bank structure 160 in the non-emission area NLA of the second display area DA2 are identical to those of the bank structure 160 in the non-emission area NLA of the first display area DA1.

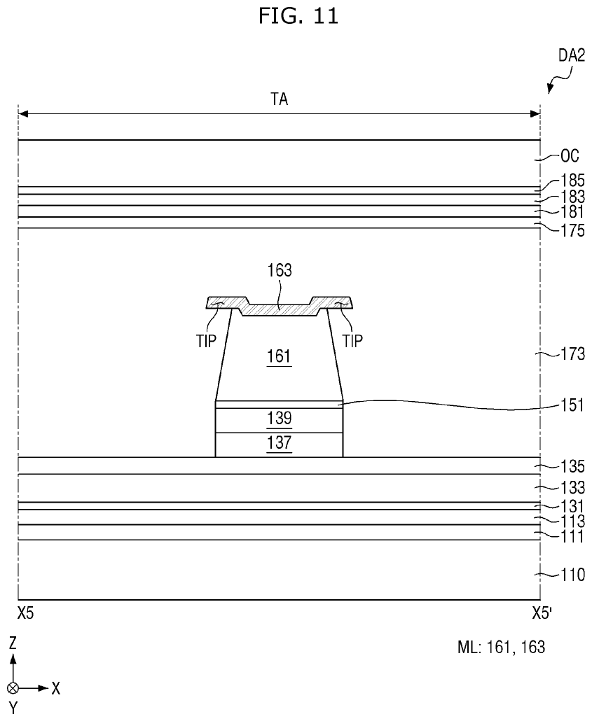

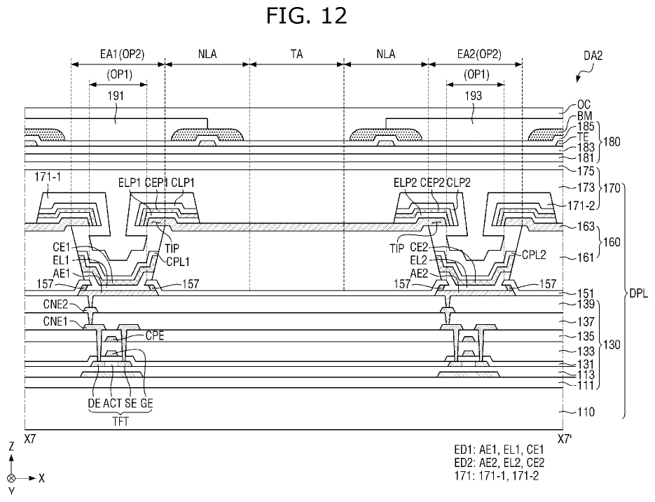

FIG. 11 is a cross-sectional view taken along line X5-X5′ of FIG. 9. FIG. 12 is a cross-sectional view taken along line X7-X7′ of FIG. 9.

Referring to FIG. 11, a schematic cross-sectional structure of a metal line ML will be described. The metal line ML disposed in the transmissive area TA may be disposed on the thin-film transistor layer 130.

The thin-film transistor layer 130 overlapping with the metal line ML may include the first buffer layer 111, the second buffer layer 113, the gate insulator 131, the first inter-dielectric layer 133, the second inter-dielectric layer 135, the first via layer 137, and the second via layer 139. The inorganic pixel-defining layer 151 may be disposed on the second via layer 139 in line with the metal line ML.

The metal line ML of the display device 10 in the embodiment may be formed via an etching process during the fabrication process. This may be the same process as the etching process for forming the plurality of emission areas EA1, EA2 and EA3 and the transmissive area TA. Specifically, in the etching process for forming the transmissive area TA, the first via layer 137, the second via layer 139, the inorganic pixel-defining layer 151 and the bank structure 160 may be etched except the metal line ML, to form the metal line ML. In this manner, the both side surfaces of the first via layer 137, the second via layer 139 and the inorganic pixel-defining layer 151 in line with the metal line ML may be aligned with one another in the first direction (x-axis direction).

In some embodiments, the metal line ML in the transmissive area TA may be integrated with the bank structure 160 in the non-emission area NLA. Accordingly, the metal line ML may include the first bank layer 161 and the second bank layer 163. The second bank layer 163 included in the metal line ML may include tips TIP that protrude from the opposite sides of the first bank layer 161. This will be described in detail later.

The first via layer 137, the second via layer 139, the inorganic pixel-defining layer 151 and the bank structure 160 in line with the metal line ML may be surrounded by the second encapsulation layer 173. In addition, the first via layer 137, the second via layer 139, the inorganic pixel-defining layer 151 and the bank structure 160 in line with the metal line ML may contact the second encapsulation layer 173. Redundant descriptions of other elements will be omitted.

Referring to FIG. 12, the metal line ML in the transmissive area TA may be integrated with the bank structure 160 in the non-emission area NLA. In other words, the bank structure 160 in the non-emission area NLA may be extended to a part of the transmissive area TA, and a portion of the bank structure 160 in the transmissive area TA may be defined as the metal line ML.

Accordingly, the metal line ML in the transmissive area TA may include the first bank layer 161 including a conductive material and the second bank layer 163. The metal line ML may electrically connect between adjacent ones of the cathode electrodes CE1, CE2 and CE3 in the emission areas EA1, EA2 and EA3.

The display device 10 in the embodiment includes the metal line ML, so that the transmissive area TA may be obtained and electrical stability of the display device 10 may be ensured. In addition, since the metal line ML may be formed simultaneously in the process of forming the bank structure 160, the process of fabricating the display device 10 in the embodiment may become easier.

FIGS. 13 to 22 are cross-sectional views sequentially showing the process of fabricating the display device 10 in the second display area DA2. Specifically, FIGS. 13 to 22 show the order of forming the bank structure 160 overlapping with the emission areas EA1 and EA2, the non-emission area NLA and the transmissive area TA, and a plurality of light-emitting elements ED1, ED2 and ED3. Hereinafter, the process of fabricating the display device 10 will be described with respect to the order of forming a variety of layers.

Referring to FIG. 13, a plurality of anode electrodes AE1 and AE2, a sacrificial layer SFL, an inorganic pixel-defining layer 151, and a plurality of bank material layers 161L and 163L are formed on the thin-film transistor layer 130. Although not shown in the drawings, the thin-film transistor layer 130 may be disposed on the substrate 110, and the structure of the thin-film transistor layer 130 has been described above with reference to FIG. 6.

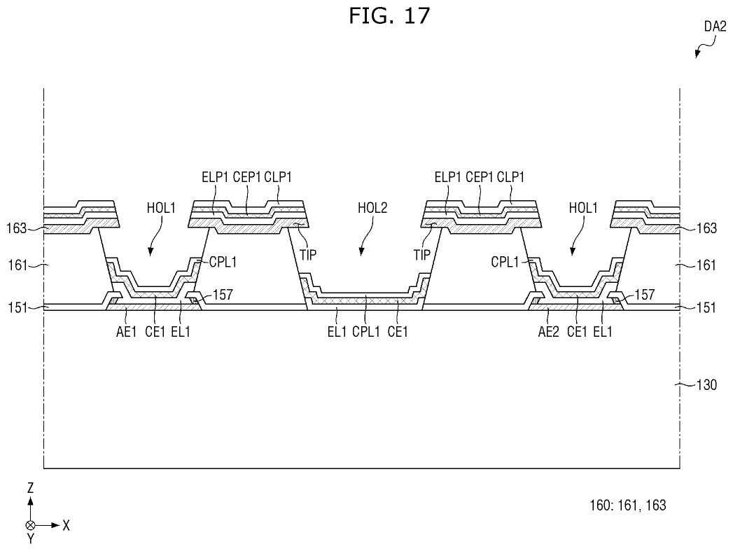

A plurality of anode electrodes AE1 and AE2 may be spaced apart from each other on the thin-film transistor layer 130. A sacrificial layer SFL may be disposed on each of the anode electrodes AE1 and AE2. The sacrificial layer SFL may be disposed on each of the anode electrodes AE1 and AE2, and then partially removed in a subsequent process to create space in which the emissive layers EL1 and EL2 (refer to FIG. 17) are disposed. The sacrificial layer SFL may prohibit the upper surfaces of the anode electrodes AE1 and AE2 from being in contact with the inorganic pixel-defining layer 151. In an embodiment, the sacrificial layer SFL may include an oxide semiconductor, for example. In an embodiment, the sacrificial layer SFL may include at least one of indium-gallium-zinc oxide (“IGZO”), zinc-tin oxide (“ZTO”), indium-tin oxide (“IZO”), etc., for example.

The inorganic pixel-defining layer 151 and the bank material layers 161L and 163L may be disposed on the anode electrodes AE1 and AE2 and the sacrificial layer SFL. The inorganic pixel-defining layer 151 may be disposed to cover an entirety of the sacrificial layer SFL and the thin-film transistor layer 130. A plurality of bank material layers 161L and 163L may be disposed entirely on the inorganic pixel-defining layer 151. The bank material layers 161L and 163L may include the first bank material layer 161L and the second bank material layer 163L. The first bank material layer 161L may be disposed directly on the inorganic pixel-defining layer 151, and the second bank material layer 163L may be disposed on the first bank material layer 161L.

The bank material layers 161L and 163L may be partially etched in a subsequent process to form the first bank layer 161 and the second bank layer 163 of the bank structure 160 shown in FIG. 6, respectively. The bank material layers 161L and 163L are substantially identical to the bank structure 160 described above; and, therefore, the redundant descriptions will be omitted.

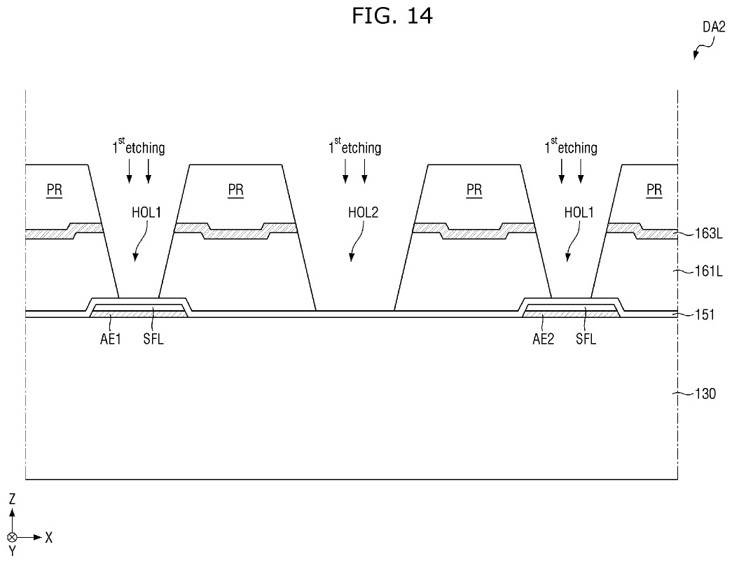

Subsequently, referring to FIG. 14, photo resists PR are formed on the second bank material layer 163L, and the first bank material layer 161L and the second bank material layer 163L are partially etched using the photo resist PR as a mask (1^{st} etching). In this process, first holes HOL1 may be defined in line with the anode electrodes AE1 and AE2. In addition, a second hole HOL2 may be defined between the anode electrodes AE1 and AE2 to form a transmissive area TA. The first holes HOL1 and the second hole HOL2 may be defined in the same process.

The photo resists PR may be separated on the bank material layers 161L and 163L. The photo resists PR may be disposed to expose portions overlapping the anode electrodes AE1 and AE2 and a portion for forming the transmissive area TA on the second bank material layers 163L.

In an embodiment, the first (1^{st}) etching process may be conducted as dry etching. As the first etching process (1^{st} etching) is conducted as a dry etching process, the bank material layers 161L and 163L including or consisting of different materials may be etched. Accordingly, the inorganic pixel-defining layer 151 overlapping each of the anode electrodes AE1 and AE2 and the transmissive area TA may be exposed.

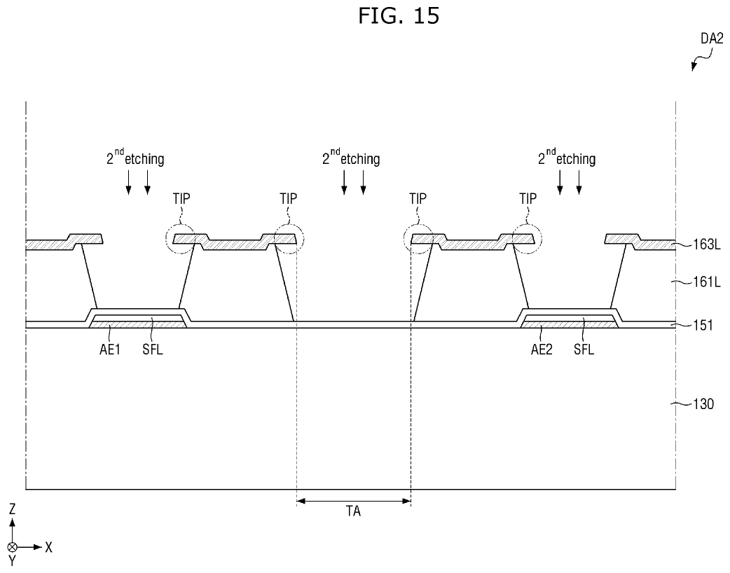

Subsequently, referring to FIG. 15, a second etching process (2^{nd} etching) for forming a tip of the bank structure 160 is conducted. In an embodiment, the second etching process may be conducted as a wet etching process. In this process, the etch rate of the first bank material layer 161L may be faster than that of the second bank material layer 163L. As a result, a tip may be formed on the side surface of the second bank material layer 163L that protrudes further than the side surface of the first bank material layer 161L. Accordingly, an undercut may be formed on the side surface of the first bank material layer 161L and under the tip of the second bank material layer 163L.

Through this process, the first bank material layer 161L and the second bank material layer 163L may be formed in the form of the first bank layer 161 and the second bank layer 163 shown in FIG. 6. In addition, as the second bank material layer 163L includes the tips via this process, the transmissive area TA shown in FIG. 10 may be defined. In other words, the transmissive area TA may be defined by the tips protruding toward the transmissive area TA of the second bank material layer 163L.

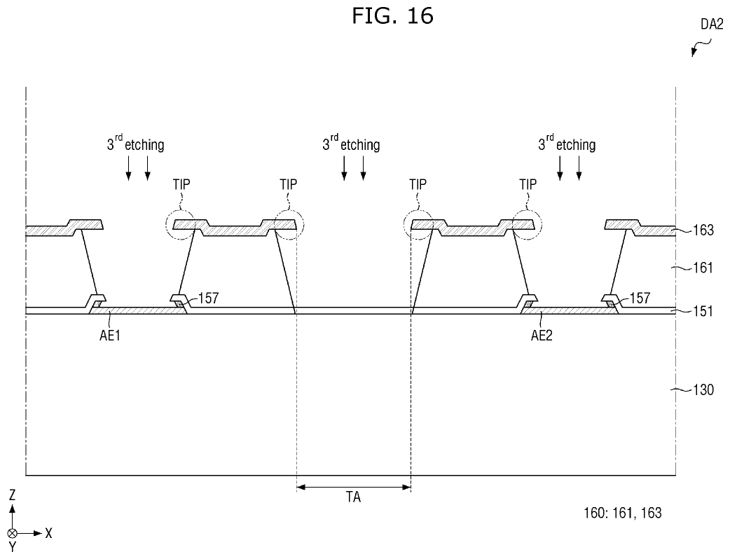

Subsequently, referring to FIG. 16, the sacrificial layer SFL and the inorganic pixel-defining layer 151 overlapping the anode electrodes AE1 and AE2 and the inorganic pixel-defining layer 151 in the transmissive area TA may be removed (3^{rd} third etching process). The third etching process may be conducted by alternately performing dry etching and wet etching processes. Specifically, first, the inorganic pixel-defining layer 151 including an inorganic film may be removed via a dry etching process. As a result, the inorganic pixel-defining layer 151 overlapping the anode electrodes AE1 and AE2 may be removed, and the sacrificial layer SFL overlapping the anode electrodes AE1 and AE2 may be exposed. At the same time, the inorganic pixel-defining layer 151 in line with the transmissive area TA may be removed, thereby exposing the thin-film transistor layer 130 in the transmissive area TA.

Second, the sacrificial layer SFL including or consisting of an oxide semiconductor may be removed via a wet etching process. In this process, portions between the inorganic pixel-defining layer 151 and the anode electrodes AE1 and AE2 may be removed, and space may be created between the inorganic pixel-defining layer 151 and the anode electrodes AE1 and AE2 in the third direction (z-axis direction). It should be noted that the sacrificial layer SFL may not be completely removed, and some remaining patterns 157 may remain in the space between the inorganic pixel-defining layer 151 and the anode electrodes AE1 and AE2. By removing the sacrificial layer SFL in this process, the anode electrodes AE1 and AE2 may be exposed.

Subsequently, referring to FIG. 17, a first emissive layer EL1, a first cathode electrode CE1 and a first capping layer CPL1 may be deposited in line with the anode electrodes AE1 and AE2 and the transmissive area TA. Specifically, the first emissive layer EL1, the first cathode electrode CE1 and the first capping layer CPL1 may be disposed on the first anode electrode AE1 and the second anode electrode AE2 in the first holes HOL1. In addition, the first emissive layer EL1, the first cathode electrode CE1 and the first capping layer CPL1 may be disposed on the thin-film transistor layer 130 in the second hole HOL2.

In addition, in the deposition process, the materials for forming the first emissive layer EL1, the first cathode electrode CE1 and the first capping layer CPL1 may also be deposited on the second bank layer 163 to form a plurality of first patterns ELP1, CEP1 and CLP1. The structure and relationships of the first emissive layer EL1, the first cathode electrode CE1 and the first capping layer CPL1, and the first organic pattern ELP1, the first electrode pattern CEP1 and the first capping pattern CLP1 have been described above; and, therefore, the redundant descriptions will be omitted

According to the embodiment, the emissive layers EL1, EL2 and EL3 may be formed via a deposition process. As the second bank layer 163 includes the protruding tips, the material of the emissive layers EL1, EL2 and EL3 may not be deposited sufficiently. Accordingly, the material of the emissive layers EL1, EL2 and EL3 may be deposited in oblique directions rather than the third direction (z-axis direction). In this manner, the material may be deposited even under the tips TIP of the second bank layer 163.

In an embodiment of the disclosure, the angle of the deposition process of forming the emissive layers EL1, EL2 and EL3 is defined as a first angle. The deposition process of forming the emissive layers EL1, EL2 and EL3 may be performed at an angle of 45° to 50° from the upper surface of the anode electrodes AE1 and AE2 and AE3. That is to say, the first angle may range from 45° to 50°.

Accordingly, the emissive layers EL1, EL2 and EL3 may be formed to fill the space between the anode electrodes AE1, AE2 and AE3 and the inorganic pixel-defining layer 151, and may be formed also on a part of the side surface of the first bank layer 161 hidden by the protruding tips TIP of the second bank layer 163.

This process may be similarly applied to the cathode electrodes CE1, CE2 and CE3.

According to the embodiment, the cathode electrodes CE1, CE2 and CE3 may be formed via a deposition process. As the second bank layer 163 includes the tips TIP, the material of the cathode electrodes CE1, CE2 and CE3 may not be deposited sufficiently. Accordingly, the material of the cathode electrodes CE1, CE2 and CE3 may be deposited in oblique directions rather than the third direction (z-axis direction). In this manner, the material may be deposited even under the tips TIP of the second bank layer 163.

In an embodiment of the disclosure, the angle of the deposition process of forming the cathode electrodes CE1, CE2 and CE3 is defined as a second angle. The deposition process of forming the cathode electrodes CE1, CE2 and CE3 may be performed obliquely with respect to the upper surface of the anode electrodes AE1 and AE2 and AE3 by an angle of 30° or less. That is to say, the second angle may be equal to or less than about 30°.

In other words, the deposition process of forming the cathode electrodes CE1, CE2 and CE3 may be performed in a relatively horizontal direction compared to the deposition process of forming the emissive layers EL1, EL2 and EL3. Accordingly, the contact area between the cathode electrodes CE1, CE2 and CE3 and the side surface of the first bank layer 161 may be larger than the contact area between the emissive layers EL1, EL2 and EL3 and the side surface of the second bank layer 163. That is to say, the deposition process of forming the cathode electrodes CE1, CE2 and CE3 may have higher step coverage than the deposition process of forming the emissive layers EL1, EL2 and EL3.

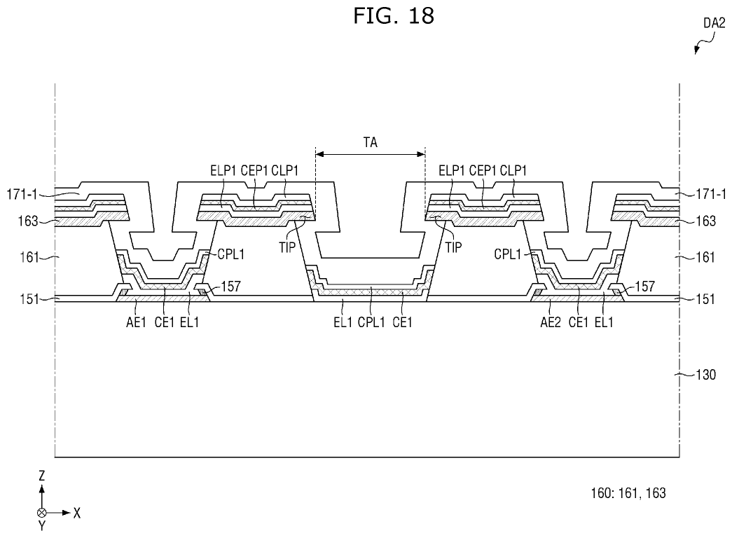

Subsequently, referring to FIG. 18, a first inorganic layer 171-1 is formed to cover the first capping layer CPL1 and the first capping pattern CLP1. The first inorganic layer 171-1 may be formed entirely on the anode electrodes AE1 and AE2 and in the transmissive area TA. The first inorganic layer 171-1 may be formed via a CVD process. The first inorganic layer 171-1 may form a uniform film regardless of the underlying structure having different heights. In an embodiment, the first inorganic layer 171-1 may also cover the protruding tips TIP of the second bank layer 163 and the undercuts formed by the first bank layer 161, for example.

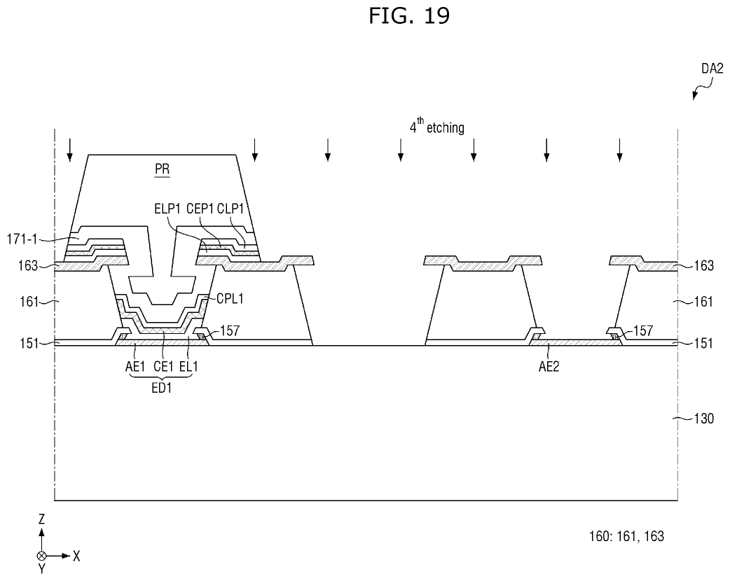

Subsequently, referring to FIG. 19, a photo resist PR is formed on the first anode electrode AE1 and parts of the bank structure 160 disposed on the opposite sides of the first anode electrode AE1, and a fourth etching (4^{th} etching) is conducted.

In this process, the first emissive layer EL1, the first cathode electrode CE1, the first capping layer CPL1, the plurality of first patterns ELP1, CEP1 and CLP1, and the first inorganic layer 171-1 where the photo resist PR is not formed may be removed, leaving the periphery of the first anode electrode AE1. In an embodiment, the process of the fourth etching may be conducted by alternately performing a wet etching process and a dry etching process. Through the above process, the first emission area EA1 shown in FIGS. 6 and 10 may be defined, and the first inorganic layer 171-1 may be formed, which covers the first light-emitting element ED1, the first capping layer CPL1, the first organic pattern ELP1, the first electrode pattern CEP1, and the first capping pattern CLP1 in line with the first emission area EA1.

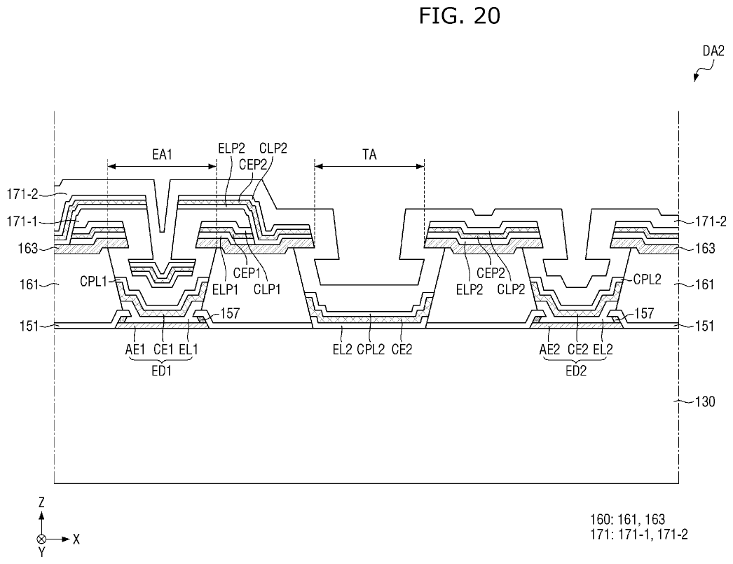

Referring to FIG. 20, processes similar to those described above are repeated, so that a second light-emitting element ED2, a second capping layer CPL2, a second organic pattern ELP2, a second electrode pattern CEP2, a second capping pattern CLP2 and a second inorganic layer 171-2 may be formed. The second light-emitting element ED2, the second capping layer CPL2, the second organic pattern ELP2, the second electrode pattern CEP2, the second capping pattern CLP2 and the second inorganic layer 171-2 may overlap not only with the second anode electrode AE2 but also with the first anode electrode AE1 and the transmissive area TA. Specifically, the second light-emitting element ED2, the second capping layer CPL2, the second organic pattern ELP2, the second electrode pattern CEP2, the second capping pattern CLP2 and the second inorganic layer 171-2 may be disposed on the first inorganic layer 171-1 in line with the first anode electrode AE1, and may be disposed on the thin-film transistor layer 130 in line with the transmissive area TA.

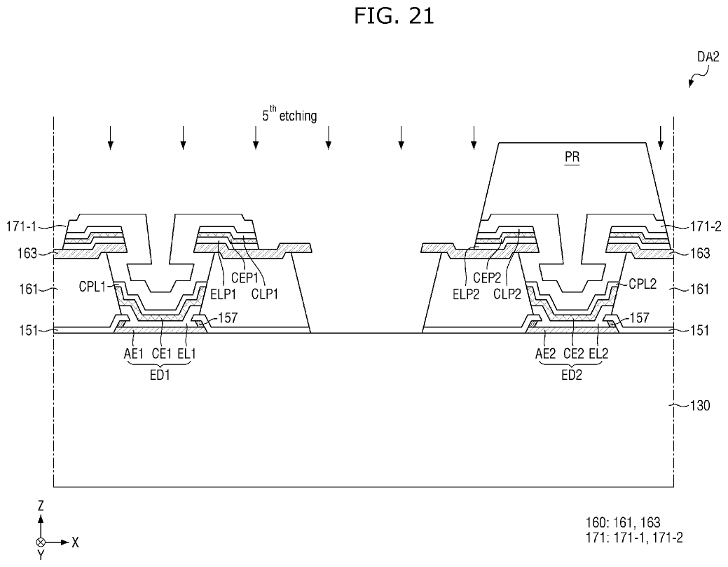

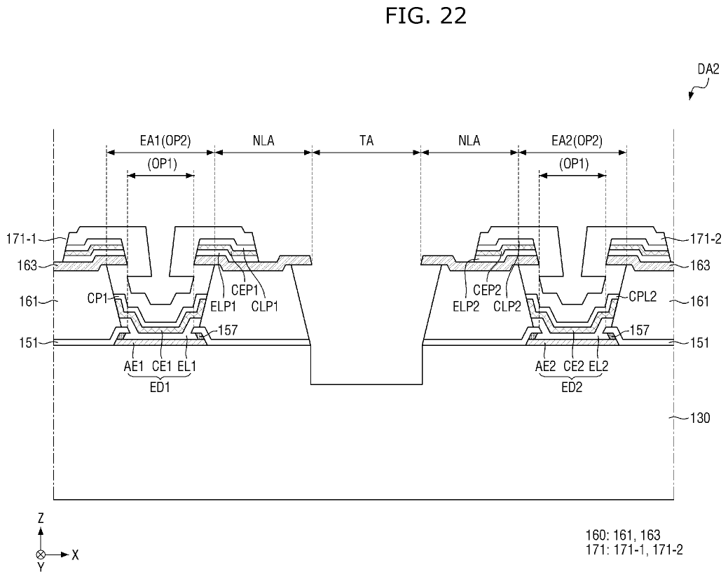

Subsequently, referring to FIGS. 21 and 22, a photo resist PR is formed on the second anode electrode AE2 and parts of the bank structure 160 disposed on the opposite sides of the second anode electrode AE2, and a fifth etching (5^{th} etching) process is conducted.

In this process, the second emissive layer EL2, the second cathode electrode CE2, the second capping layer CPL2, the plurality of second patterns ELP2, CEP2 and CLP2, and the second inorganic layer 171-2 where the photo resist PR is not formed may be removed, leaving the periphery of the second anode electrode AE2. In an embodiment, the process of the fifth etching may be conducted by alternately performing a wet etching process and a dry etching process. Through the above process, the second emission area EA2 shown in FIG. 10 may be defined, and a second inorganic layer 171-2 may be formed, which covers the second light-emitting element ED2, the second capping layer CPL2, the second organic pattern ELP2, the second electrode pattern CEP2 and the second capping pattern CLP2 in line with the second emission area EA2.

Subsequently, in this process, the first via layer 137 and the second via layer 139 of the thin-film transistor layer 130 may be removed in the transmissive area TA. It should be understood, however, that the disclosure is not limited thereto. When the first via layer 137 and the second via layer 139 include or consist of a transparent material, the first via layer 137 and the second via layer 139 may not be removed.

Referring to FIG. 22, the first emission area EA1, the second emission area EA2, the non-emission area NLA and the transmissive area TA shown in FIG. 10 may be formed via the above-described processes. In addition to the foregoing description, the emission areas EA1, EA2 and EA3 may be defined by a first opening OP1 defined by the inorganic pixel-defining layer 151 and a second opening OP2 formed by the bank structure 160. The transmissive area TA may be defined by the tips TIP of the bank structure 160 facing the transmissive area TA. The non-emission area NLA may be defined by the emission areas EA1, EA2 and EA3 and the transmissive area TA.

Although not shown in the drawings, a second encapsulation layer 173 and a third encapsulation layer 175 may be formed on the first encapsulation layers 171 and the bank structure 160 to form a thin-film encapsulation layer 170. Subsequently, a touch sensor layer 180, a light-blocking layer BM, a color filter layer 190, and an overcoat layer OC are formed, so that the display device 10 shown in FIG. 6 may be fabricated.

However, the effects of the disclosure are not restricted to the one set forth herein. The above and other effects of the disclosure will become more apparent to one of daily skill in the art to which the disclosure pertains by referencing the claims.

What is claimed is:

1. A display device comprising:
a substrate comprising a first emission area, a transmissive area, and a non-emission area disposed between the first emission area and the transmissive area;
a pixel-defining layer disposed on the non-emission area of the substrate and defining a first opening;
a bank structure disposed on the pixel-defining layer, defining a second opening, and comprising different materials, the bank structure comprising:
a first bank layer comprising a conductive material; and
a second bank layer disposed on the first bank layer and comprising tips which protrude on opposite sides of the second bank layer further toward the first opening and the transmissive area further than side surfaces of the first bank layer; and
a first light-emitting element located on the first emission area of the substrate and in contact with the bank structure.

2. The display device of claim 1, wherein a tip of the tips of the second bank layer which protrudes toward the transmissive area; and the tip of the second bank layer which protrudes toward the first opening form undercuts with the side surfaces of the first bank layer.

3. The display device of claim 1, wherein the first light-emitting element comprises
an anode electrode disposed on the substrate;
an emissive layer on the anode electrode in line with the first opening; and
a cathode electrode on the emissive layer, and
wherein the emissive layer and the cathode electrode contact a side surface of the side surfaces of the first bank layer in the second opening.

4. The display device of claim 3, wherein the cathode electrode covers an entirety of the emissive layer on the side surfaces of the first bank layer.

5. The display device of claim 4, wherein the first bank layer comprises aluminum, and the second bank layer comprises titanium.

6. The display device of claim 3, further comprising:
an organic pattern disposed on the second bank layer, surrounding the first opening, and comprising a same material as a material of the emissive layer; and
an electrode pattern disposed on the organic pattern and comprising a same material as a material of the cathode electrode.

7. The display device of claim 6, wherein the emissive layer and the organic pattern are spaced apart from each other, and
wherein the cathode electrode and the electrode pattern are spaced apart from each other.

8. The display device of claim 7, wherein the organic pattern and the electrode pattern do not overlap with a tip of the tips of the second bank layer which protrudes toward the transmissive area.

9. The display device of claim 1, wherein the second opening surrounds an entirety of the first opening in a plan view.

10. The display device of claim 9, wherein the non-emission area surrounds an entirety of the first emission area in the plan view, and wherein the transmissive area surrounds the non-emission area.

11. The display device of claim 1, wherein the transmissive area comprises an optical device.

12. The display device of claim 1, further comprising:
a second emission area spaced apart from the first emission area with the non-emission area and the transmissive area therebetween; and
a second light-emitting element disposed on the substrate in line with the second emission area.

13. The display device of claim 12, further comprising:
a metal line overlapping with the transmissive area and electrically connecting the first light-emitting element with the second light-emitting element.

14. The display device of claim 13, wherein the metal line comprises the first bank layer and the second bank layer in the transmissive area.

15. The display device of claim 13, wherein the first bank layer and the second bank layer included in the bank structure in the non-emission area are integral with the first bank layer and the second bank layer included in the metal line in the transmissive area.

16. The display device of claim 13, wherein the first emission area and the second emission area are connected with each other by the metal line in a plan view.

17. The display device of claim 16, wherein the transmissive area is surrounded by the tip of the second bank layer which protrudes toward the transmissive area in the plan view.

18. A method of fabricating a display device, the method comprising:
forming a sacrificial layer on each of a plurality of anode electrodes spaced apart from one another on an emission area of a substrate, the substrate comprising the emission area and a transmissive area, forming a pixel-defining layer disposed on the sacrificial layer and the substrate and covering an entirety of the sacrificial layer and the substrate, and forming a first bank material layer and a second bank material layer on the pixel-defining layer;
defining a first hole overlapping with the plurality of anode electrodes, penetrating the first bank material layer and the second bank material layer and exposing the pixel-defining layer overlapping the plurality of anode electrodes, and defining a second hole overlapping with the transmissive area, penetrating the first bank material layer and the second bank material layer and exposing the pixel-defining layer in the transmissive area;
performing wet etching on sidewalls of the first hole and the second hole to form a tip where the second bank material layer protrudes toward the transmissive area further than sidewalls of the first bank material layer;
removing portions of the pixel-defining layer overlapping with the plurality of anode electrodes and the transmissive area by dry etching, removing portions of the sacrificial layer overlapping with the plurality of anode electrodes by wet etching, to exposes the plurality of anode electrodes;
forming an emissive layer and a cathode electrode on the plurality of anode electrodes, the substrate overlapping with the transmissive area and the second bank material layer, and forming a first encapsulation layer over the cathode electrode; and
removing the emissive layer, the cathode electrode and the first encapsulation layer except the emissive layer, the cathode electrode and the first encapsulation layer disposed in and around the emission area,
wherein the second bank material layer comprises the tip which protrudes toward the transmissive area.

19. The method of claim 18, wherein the tip of the second bank material layer which protrudes toward the transmissive area does not overlap with the emissive layer or the cathode electrode.

20. The method of claim 19, wherein the transmissive area is surrounded by the tip which protrudes toward the transmissive area in a plan view.
